(19) United States
(12) Patent Application Publication
(10) Pub. No.: US 2025/0385231 A1
(43) Pub. Date: Dec. 18, 2025

(54) INTERPOSER FOR SEMICONDUCTOR PACKAGE INCLUDING INTEGRATED PHOTONIC COMPONENTS AND METHODS OF FABRICATION THEREOF

(71) Applicant: Taiwan Semiconductor Manufacturing Company Limited, Hsinchu (TW)

(72) Inventors: Ming-Han LIAO, Hsinchu (TW); Chih-Hao WANG, Baoshan Township (TW); Min CAO, Hsinchu (TW)

(21) Appl. No.: 18/929,488

(22) Filed: Oct. 28, 2024

Related U.S. Application Data
(60) Provisional application No. 63/658,957, filed on Jun. 12, 2024.

(51) Int. Cl. H01L 25/16; G02B 6/028; G02B 6/036; G02B 6/13; G02B 6/42; H01L 21/48; H01L 23/00; H01L 23/498; H10B 80/00

(52) U.S. Cl. CPC H01L 25/167; G02B 6/028; G02B 6/03622; G02B 6/13; G02B 6/4214; H01L 21/4857; H01L 23/49833; H01L 23/49838; H01L 24/08; H01L 24/16; H01L 24/80; H01L 2224/08145; H01L 2224/16227; H01L 2224/16238; H01L 2224/80895; H01L 2224/80896; H01L 2924/14361; H10B 80/00

(57) ABSTRACT

Interposers for semiconductor packages including photonic components, such as an optical waveguide and/or an integrated circuit (IC) photonic die, integrated into the interposer. The interposer includes a substrate, a redistribution structure over the substrate, where the redistribution structure includes a plurality of conductive features in a dielectric material, and an optical waveguide located over and/or within the substrate. The optical waveguide includes a core material surrounded by a cladding material, where the core material has an index of refraction that is greater than an index of refraction of the cladding material, and the optical waveguide is configured to transmit optical signals through the interposer to and/or from an IC photonic die electrically coupled to an IC electronic die that provides an interface between electronic and photonic components of the semiconductor package. In various embodiments, improved data transport bandwidth and energy efficiency in the semiconductor package may be provided.

### RELATED APPLICATIONS

This application claims the benefit of priority to U.S. Provisional Application No. 63/658,957, entitled “Novel Interposer Structure with Photon Transmission for Si Photonic High Bandwidth Connections,” filed on Jun. 12, 2024, the entire contents of which are incorporated by reference herein for all purposes.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens, hundreds, or thousands of integrated circuits are typically manufactured on a single semiconductor wafer, and individual dies on the wafer are singulated by sawing between the integrated circuits along scribe lines. The individual dies are typically packaged separately, in multi-chip modules, or in other types of packaging, for example. However, there are many challenges related to fabricating and operating large, multi-chip packages, such as limited data transport bandwidth to and between different components of the package and low energy efficiency.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of an intermediate interposer structure according to various embodiments of the present disclosure.

FIG. 2 is a vertical cross-sectional view of an intermediate interposer structure illustrating a first cladding material and a core material formed over the first side of the substrate according to various embodiments of the present disclosure.

FIG. 3A is top view of the intermediate interposer structure illustrating a patterned mask formed over the core material according to various embodiments of the present disclosure.

FIG. 3B is a vertical cross-sectional view of an intermediate interposer structure taken along line A-A′ in FIG. 3A.

FIG. 4A is a top view of the intermediate interposer structure following an etching process that removes portions of the core material and the first cladding material according to various embodiments of the present disclosure.

FIG. 4B is a vertical cross-sectional view of an intermediate interposer structure taken along line B-B′ in FIG. 4A.

FIG. 5A is a top view of the intermediate interposer structure illustrating a second cladding material formed over the first side of the substrate and over the first cladding material and the core material according to various embodiments of the present disclosure.

FIG. 5B is a vertical cross-sectional view of an intermediate interposer structure taken along line C-C′ in FIG. 5A.

FIG. 5C is a vertical cross-sectional view of an intermediate interposer structure taken along line D-D′ in FIG. 5A.

FIG. 6A is a top view of an intermediate interposer structure illustrating a patterned mask formed over the first side of the substrate according to various embodiments of the present disclosure.

FIG. 6B is a vertical cross-sectional view of an intermediate interposer structure taken along line E-E′ in FIG. 6A.

FIG. 7A is a top view of the intermediate interposer structure following an etching process that forms a recess in the first side of the substrate according to various embodiments of the present disclosure.

FIG. 7B is a vertical cross-sectional view of an intermediate interposer structure taken along line F-F′ in FIG. 7A.

FIG. 7C is a vertical cross-sectional view of an intermediate interposer structure taken along line G-G′ in FIG. 7A.

FIG. 8A is a top view of the intermediate interposer structure illustrating a core material formed in the recess in the first side of the substrate according to various embodiments of the present disclosure.

FIG. 8B is a vertical cross-sectional view of an intermediate interposer structure taken along line H-H′ in FIG. 8A.

FIG. 8C is a vertical cross-sectional view of an intermediate interposer structure taken along line I-I′ in FIG. 8A.

FIG. 9A is a top view of the intermediate interposer structure illustrating a second cladding material formed over the first side of the substrate and the upper surface of the core material according to various embodiments of the present disclosure.

FIG. 9B is a vertical cross-sectional view of an intermediate interposer structure taken along line J-J′ in FIG. 9A.

FIG. 9C is a vertical cross-sectional view of an intermediate interposer structure taken along line K-K′ in FIG. 9A.

FIG. 10 is a vertical cross-sectional view of an intermediate interposer structure illustrating a patterned mask formed over the upper surface of the second cladding material according to various embodiments of the present disclosure.

FIG. 11 is a vertical cross-sectional view of an intermediate interposer structure following an etching process that forms a recess through the second cladding material and into the substrate according to various embodiments of the present disclosure.

FIG. 12 is a vertical cross-sectional view of an intermediate interposer structure illustrating an integrated circuit (IC) photonic die located in the recess according to various embodiments of the present disclosure.

FIG. 13 is a vertical cross-sectional view of an intermediate interposer structure illustrating an IC electronic die located within the recess and bonded to the IC photonic die according to various embodiments of the present disclosure.

FIG. 14 is a vertical cross-sectional view of an interposer including a redistribution structure according to various embodiments of the present disclosure.

FIG. 15 is a vertical cross-sectional view of a package structure including a first semiconductor die and a second semiconductor die mounted to the interposer according to various embodiments of the present disclosure.

FIG. 16 is a vertical cross-sectional view of a semiconductor package including a package structure having an interposer with a plurality of semiconductor dies located thereon mounted to a package substrate according to various embodiments of the present disclosure.

FIG. 17 is a vertical cross-sectional view illustrating a package structure according to another embodiment of the present disclosure.

FIG. 18 is a vertical cross-sectional view of an intermediate interposer structure including a patterned mask over an upper surface of a second cladding layer according to various embodiments of the present disclosure.

FIG. 19 is a vertical cross-sectional view of an intermediate interposer structure following an etching process that forms an opening in the second cladding material according to various embodiments of the present disclosure.

FIG. 20A is a vertical cross-sectional view of an intermediate interposer structure including an optical component in the form of a triangular-shaped mirror located in the opening in the second cladding material according to various embodiments of the present disclosure.

FIG. 20B is a vertical cross-sectional view of an intermediate interposer structure including an optical component in the form of a grating located in the opening in the second cladding material according to various embodiments of the present disclosure.

FIG. 20C is a vertical cross-sectional view of an intermediate interposer structure including an optical component in the form of a bubble-shaped element located in the opening in the second cladding material according to various embodiments of the present disclosure.

FIG. 21 is a vertical cross-sectional view of an intermediate interposer structure including a second core material within the opening in the second cladding material according to various embodiments of the present disclosure.

FIG. 22 is a vertical cross-sectional view of a package structure according to various embodiments of the present disclosure.

FIG. 23 is a vertical cross-sectional view of a package structure according to another embodiment of the present disclosure.

FIG. 24 is a vertical cross-sectional view of a package structure according to another embodiment of the present disclosure.

FIG. 25 is a vertical cross-sectional view of a package structure including a first interposer and a second interposer according to another embodiment of the present disclosure.

FIG. 26 is a vertical cross-sectional view of a package structure including a first interposer and a second interposer according to another embodiment of the present disclosure.

FIG. 27 is a flowchart illustrating a method of fabricating an interposer for a semiconductor package according to various embodiments of the present disclosure.

### DETAILED DESCRIPTION

The following disclosure provides many different embodiments, or examples, for implementing various features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, this disclosure may repeat reference numerals and/or letters in the disclosed example embodiments. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Typically, in a semiconductor package, a number of semiconductor integrated circuit (IC) dies (i.e., “chips”) may be mounted onto a common substrate, which may also be referred to as a “package substrate.” The semiconductor IC dies of the package may include various types of dies, such as logic die(s) (e.g., CPU die(s), GPU die(s), ASIC die(s), etc.), memory die(s) (e.g., SRAM die(s), HBM die(s), etc.), analog die(s), RF die(s), and the like. In some cases, the semiconductor IC dies of the semiconductor package may include one or more integrated circuit (IC) photonic dies including optical components (e.g., light source(s), optical detector(s), optical modulator(s), etc.) that may be configured to generate, transmit, receive and/or modify optical signals (i.e., photons). Each IC photonic die may be operatively coupled to an IC electronic die that may be configured to provide an interface between photonic and electronic components of the semiconductor package. An IC photonic die utilizing optical signals may provide higher bandwidth and speed and lower power consumption than an equivalent IC die utilizing only electrical signals.

A semiconductor package may also include an intermediate component, known as an “interposer,” that is located between the package substrate and semiconductor IC dies of the semiconductor package. The interposer may be composed of a suitable structural material, such as a semiconductor (e.g., silicon), glass, or organic material, and may include conductive interconnect structures extending through the interposer. A plurality of semiconductor IC dies, which may include all of the semiconductor IC dies of the package, may be mounted over a first side of the interposer, and a second side of the interposer may be mounted to the package substrate. The interposer may provide electrical interconnections between different dies mounted to the interposer and may also electrically connect the dies on the interposer to the underlying package substrate. In some cases, some of the dies of the semiconductor package may be coupled to the package substrate via an interposer, while other dies may be directly mounted to the package substrate.

Connections between different dies (e.g., logic dies, memory dies, IC photonics dies, etc.) of a semiconductor package are typically made via electrical signals transmitted through conductive interconnect structures within the interposer and/or the package substrate. This can result in limited data transport bandwidth and low energy efficiency (e.g., >3 pJ/bit).

The various embodiments disclosed herein may include an interposer structure for a semiconductor package that includes photonic components, such as one or more optical waveguides and/or one or more IC photonic dies, integrated into an interposer of the semiconductor package. In one embodiment, an interposer for a semiconductor package may include a substrate, a redistribution structure over the substrate, where the redistribution structure includes a plurality of conductive features in a dielectric material, and an optical waveguide located over and/or within the substrate. The optical waveguide may include a core material surrounded by a cladding material, where the core material has an index of refraction that is greater than an index of refraction of the cladding material. The optical waveguide may be used to transmit optical signals through the interposer to and/or from one or more IC photonic dies that may be electrically coupled to one or more IC electronic dies. The one or more IC electronic dies may provide an interface between electronic components of the semiconductor package, such as one or more semiconductor dies mounted to the interposer, and photonic components of the semiconductor package, including one or more optical waveguides and IC photonic dies.

In various embodiments, providing photonic components, such as optical waveguide(s) and optionally IC photonic die(s), within the interposer of the semiconductor package may effectively improve data transport bandwidth density and energy efficiency of the semiconductor package. Providing photonic components within the interposer may enable the photonic components to be closer to the semiconductor dies, including the processing or “core” device(s) of the semiconductor package, which may help to increase data transport speed and bandwidth and improve energy efficiency of the semiconductor package. In one non-limiting embodiment, providing optical (i.e., photon) transport within the interposer of the semiconductor package may enable data transport between semiconductor dies of the semiconductor package with a high bandwidth density (e.g., >4 Tbps/mim) while also providing low energy consumption (e.g., <1 pJ/bit).

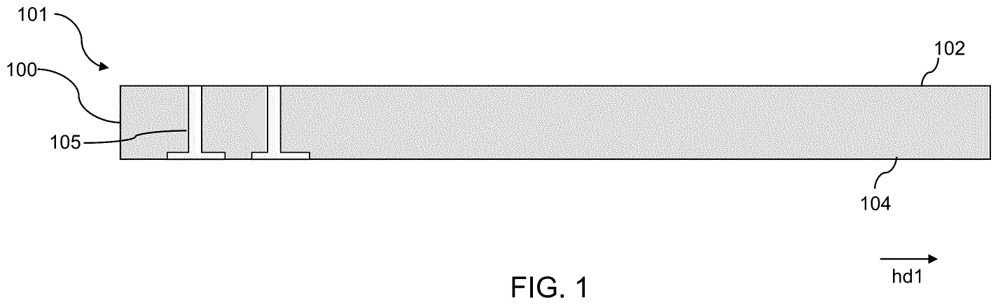

FIGS. 1-5C are sequential illustrations illustrating a process of forming an optical waveguide on an interposer structure for a semiconductor package according to various embodiments of the present disclosure. FIG. 1 is a vertical cross-sectional view of an intermediate interposer structure 101 according to various embodiments of the present disclosure. Referring to FIG. 1, the intermediate interposer structure 101 may include a substrate 100 having a first side 102 and a second side 104 opposite the first side 102. The substrate 100 may include a suitable structural material that may support a plurality of semiconductor IC dies mounted over the first side 102 of the substrate 100. In one non-limiting embodiment, the substrate 100 may include a semiconductor material (e.g., silicon). The semiconductor material may include, for example, a semiconductor wafer, or a portion thereof. Other suitable materials for the substrate 100, such as a glass or organic material, may also be utilized. A plurality of through-substrate vias 105 including an electrically conductive material may extend through the substrate 100 between the first side 102 and the second side 104 of the substrate 100.

In some embodiments, a plurality of interposer structures may be formed on different regions of a common substrate 100, such as a semiconductor wafer. A dicing process may be used to separate different regions of the substrate 100 to provide individual interposers.

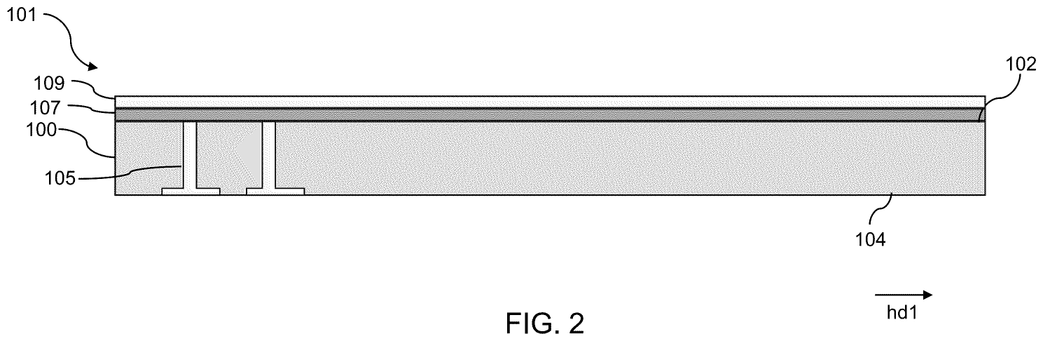

FIG. 2 is a vertical cross-sectional view of the intermediate interposer structure 101 illustrating a first cladding material 107 and a core material 109 formed over the first side 102 of the substrate 100 according to various embodiments of the present disclosure. Referring to FIG. 2, a first cladding material 107 may be deposited over the first side 102 of the substrate 100. In various embodiments, the first cladding material 107 may include a suitable dielectric material, such as silicon oxide (SiO₂), silicon nitride (SiN), alumina (Al₂O₃), silica glass (e.g., fluorine-doped silica), a polymer-based dielectric material (e.g., silicone, a fluoropolymer material, etc.), and the like. Other suitable materials for the first cladding material 107 are within the contemplated scope of disclosure. In various embodiments, the first cladding material 107 may be deposited using any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like, including various combinations thereof. The first cladding material 107 may be formed as a continuous layer over the entire first surface 102 of the substrate 100.

Referring again to FIG. 2, a core material 109 may be deposited over the first cladding material 107. In various embodiments, the core material 109 may have an index of refraction that is higher than the index of refraction of the first cladding material 107. In some embodiments, the core material 109 may include a semiconductor material, such as silicon (Si), gallium arsenide (GaAs), or the like. Other suitable materials, such as silica glass, doped silica glass, a polymer-based material (e.g., polycarbonate, PMMA, etc.), silicon nitride, etc., may also be utilized for the core material 109. The core material 109 may be deposited using a suitable deposition process as described above. In some embodiments, one or more parameters of the deposition process used to form the core material 109, such as reactant flow ratio(s), pressure, ion source energy, etc., may be controlled to increase the index of refraction of the deposited core material 109. The core material 109 may be formed as a continuous layer over the first cladding material 107.

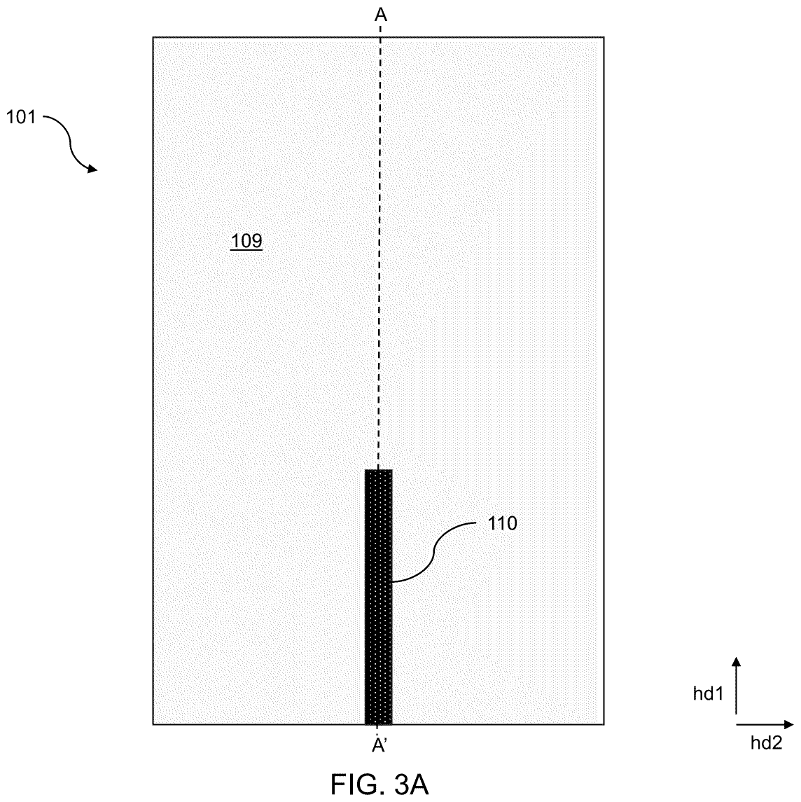

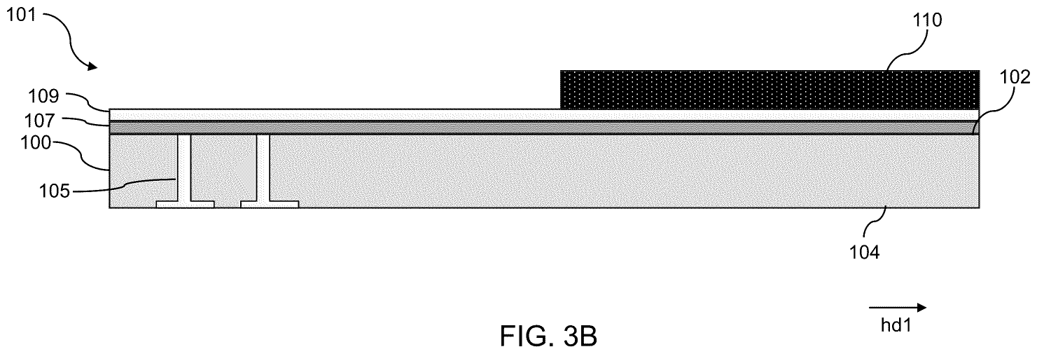

FIG. 3A is top view of the intermediate interposer structure 101 illustrating a patterned mask 110 formed over the core material 109 according to various embodiments of the present disclosure. FIG. 3B is a vertical cross-sectional view of the intermediate interposer structure 101 taken along line A-A′ in FIG. 3A. Referring to FIGS. 3A and 3B, in various embodiments, the patterned mask 110 may be formed by depositing a layer of photoresist material over the core material 109. The layer of photoresist material may be patterned using photolithographic techniques to provide a patterned mask 110 covering a portion of the core material 109, where a remaining portion of the core material 109 may be exposed through the patterned mask 110. As shown in FIGS. 3A and 3B, the patterned mask 110 may include a strip-shaped portion extending along a first horizontal direction hd1. However, it will be understood that other shapes for the patterned mask 110 are within the contemplated scope of disclosure. In addition, although FIGS. 3A and 3B illustrate a single strip-shaped portion formed over the intermediate interposer structure 101, it will be understood that the patterned mask 110 may include a number of strip-shaped portions, including an interconnected network of strip-shaped portions extending over the core material 109.

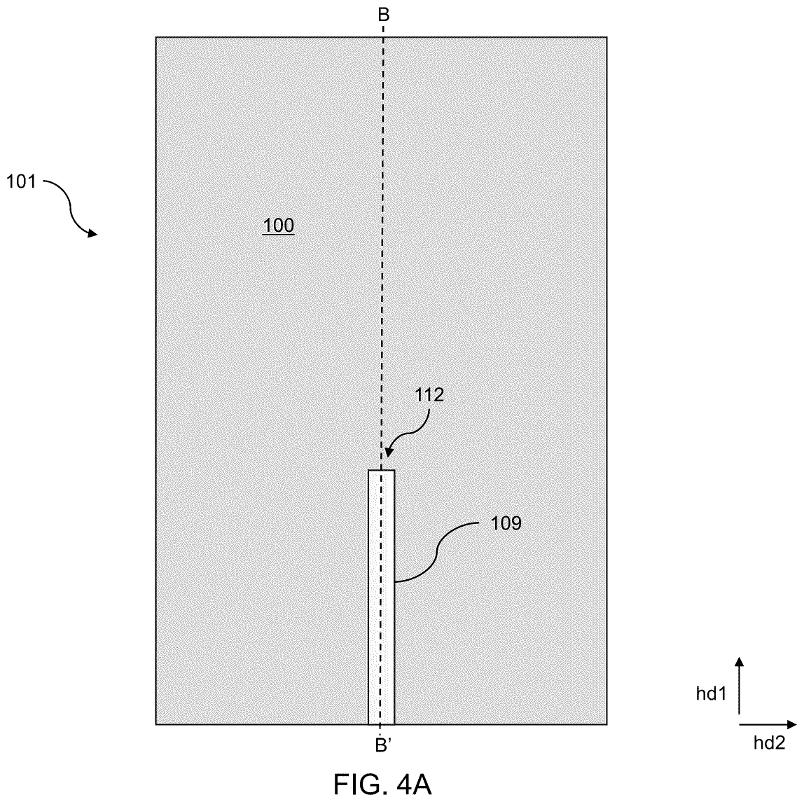

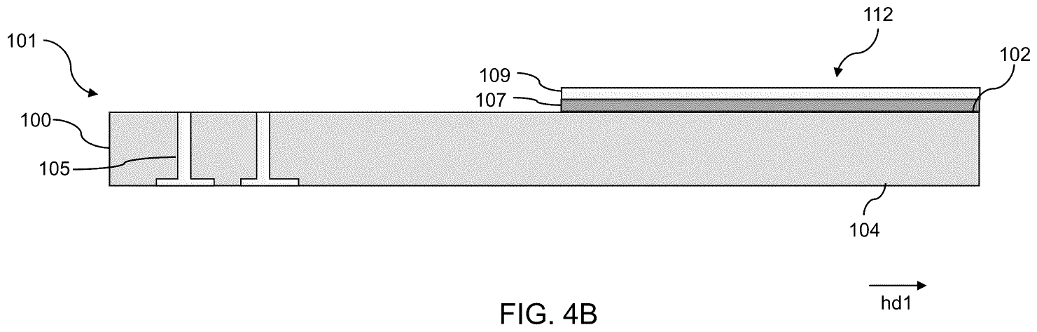

FIG. 4A is a top view of the intermediate interposer structure 101 following an etching process that removes portions of the core material 109 and the first cladding material 107 according to various embodiments of the present disclosure. FIG. 4B is a vertical cross-sectional view of the intermediate interposer structure 101 taken along line B-B′ in FIG. 4A. Referring to FIGS. 4A and 4B, an etching process may be performed through the patterned mask 110 to remove portions of the core material 109 and the first cladding material 107 that are exposed through the patterned mask 110. The etching process may expose the first side 102 of the substrate 100. Following the etching process, the patterned mask 110 may be removed using a suitable process, such as via ashing or dissolution using a solvent. Remaining portions of the core material 109 and the first cladding material 107 may form a strip-shaped layer stack 112 including the core material 109 overlying the first cladding material 107. In various embodiments, sidewalls of the first cladding material 107 may be continuous with sidewalls of the core material 109 in the strip-shaped layer stack 112. In some embodiments, the sidewalls of the first cladding material 107 and the core material 109 may be vertical sidewalls. Alternatively, one or more of the sidewalls may be angled or curved. Although FIGS. 4A and 4B illustrate a single strip-shaped layer stack 112, it will be understood that a plurality of strip-shaped layer stacks 112 such as shown in FIGS. 4A and 4B, including an interconnected network of strip-shaped layer stacks 112, may be formed over the first side 102 of the substrate 100.

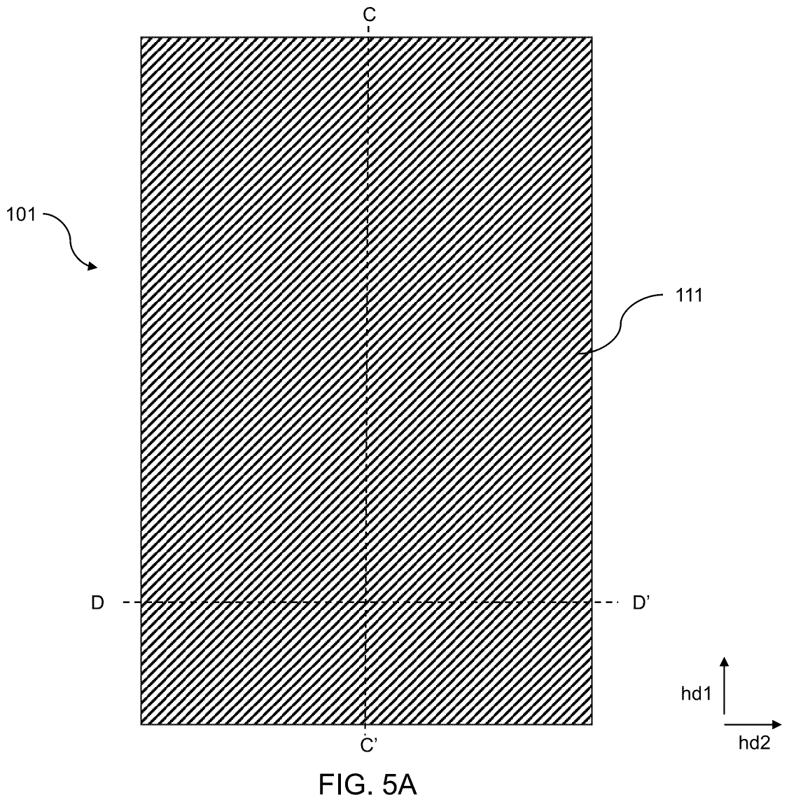

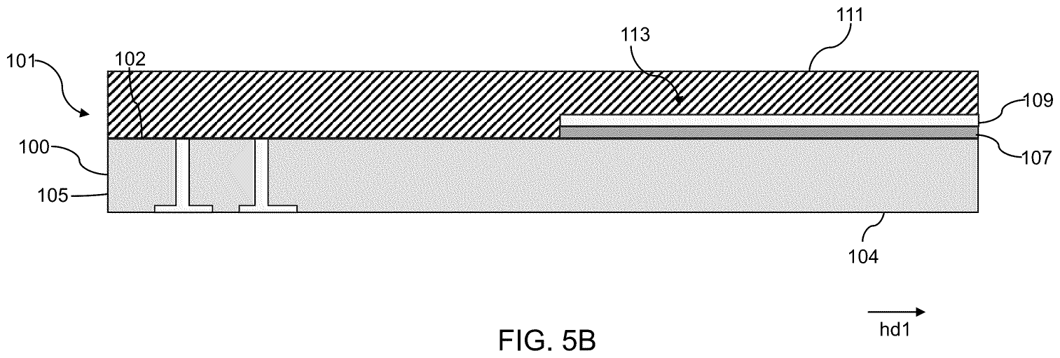

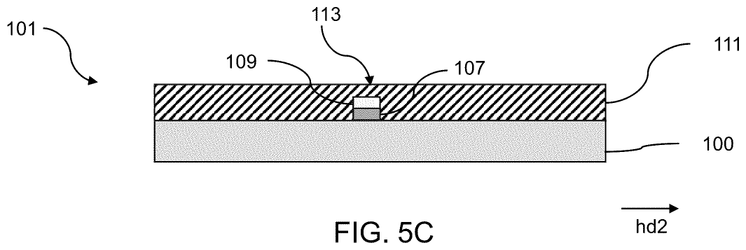

FIG. 5A is a top view of the intermediate interposer structure 101 illustrating a second cladding material 111 formed over the first side 102 of the substrate 100 and over the first cladding material 107 and the core material 109 according to various embodiments of the present disclosure. FIG. 5B is a vertical cross-sectional view of the intermediate interposer structure 101 taken along line C-C′ in FIG. 5A. FIG. 5C is a vertical cross-sectional view of the intermediate interposer structure 101 taken along line D-D′ in FIG. 5A. Referring to FIGS. 5A-5C, a second cladding material 111 may be deposited over the first side 102 of the substrate 100, over side surfaces of the first cladding material 107, and over side surfaces and the upper surface of the core material 109. The second cladding material 111 may be deposited using a suitable deposition process as described above.

The second cladding material 111 may have an index of refraction that is lower than the index of refraction of the core material 109. In various embodiments, the second cladding material 111 may include a suitable dielectric material as described above with reference to the first cladding material 107. In some embodiments, the second cladding material 111 may include the same material as the first cladding material 107. Alternatively, the second cladding material 111 may have a different composition than the first cladding material 107.

The first cladding material 107, the second cladding material 111 and the core material 109 may together form an optical waveguide 113. The optical waveguide 113 may include the core material 109 surrounded on the bottom surface of the core material 109 by the first cladding material 107 and on the side surfaces and the upper surface of the core material 109 by the second cladding material 111. Thus, the optical waveguide 113 includes a core material 109 that is surrounded on four sides by cladding material 107, 111 having a relatively lower index of refraction than the index of refraction of the core material 109. Accordingly, optical signals (i.e., photons) may propagate through the core material 109 via total internal reflection along the length of the optical waveguide 113 (i.e., along the first horizontal direction hd1 in FIGS. 5A-5C). Although FIGS. 5A-5C illustrate a single optical waveguide 113, it will be understood that a plurality of optical waveguides 113 may be formed in the intermediate interposer structure 101.

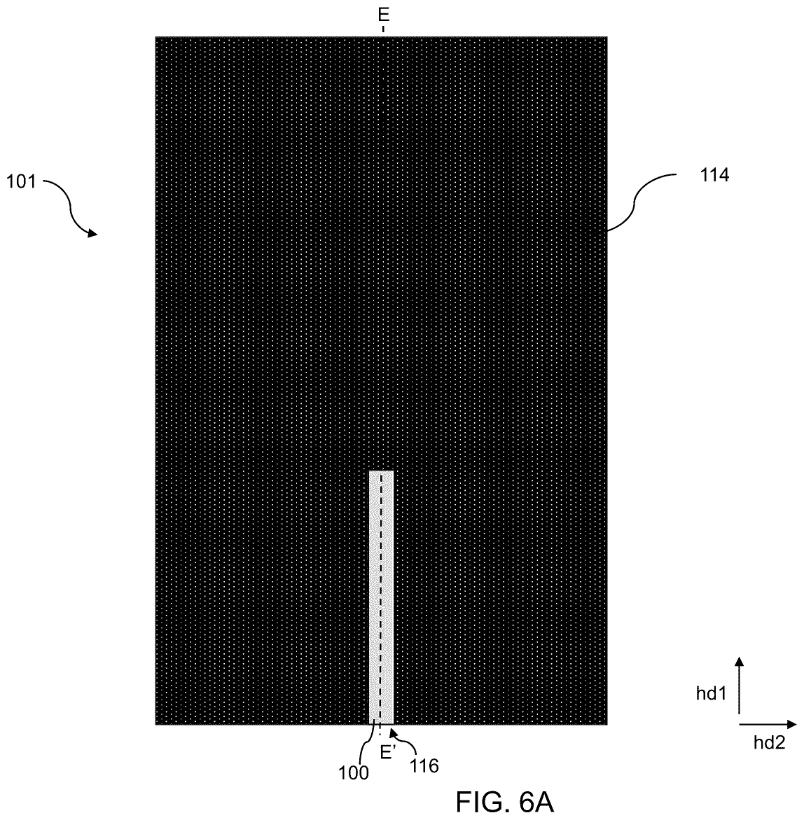

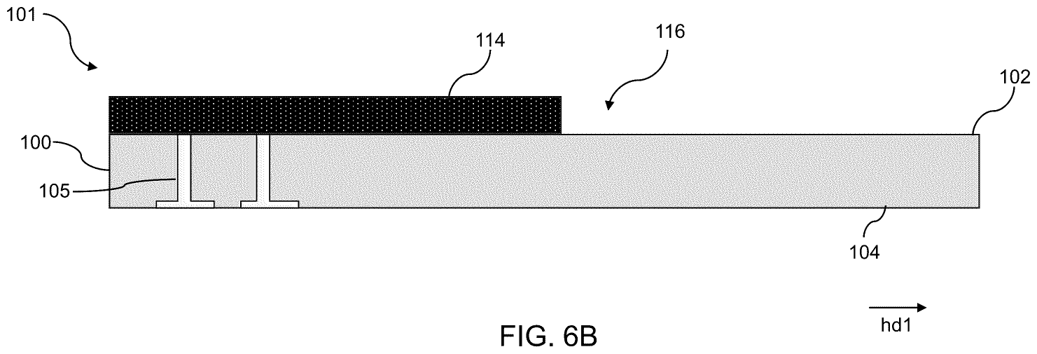

FIGS. 6A-9C illustrate a process of forming an optical waveguide 113 in an intermediate interposer structure 101 according to another embodiment of the present disclosure. FIG. 6A is a top view of an intermediate interposer structure 101 illustrating a patterned mask 114 formed over the first side 102 of the substrate 100 according to various embodiments of the present disclosure. FIG. 6B is a vertical cross-sectional view of the intermediate interposer structure 101 taken along line E-E′ in FIG. 6A. Referring to FIGS. 6A and 6B, the intermediate interposer structure 101 may include a substrate 100 as described above with reference to FIG. 1. Thus, repeated discussion of like features is omitted for brevity. In one non-limiting embodiment, the substrate 100 may include a glass material. However, other suitable materials for the substrate 100 are within the contemplated scope of disclosure.

A patterned mask 114 may be formed over the first side 102 of the substrate 100. The patterned mask 114 may be formed by depositing a layer of photoresist material over the first side 102 of the substrate 100. The layer of photoresist material may be patterned using photolithographic techniques to provide a patterned mask 114 including an opening 116 in the mask 114, where the first side 102 of the substrate 100 may be exposed through the opening 116 in the mask 114. As shown in FIGS. 6A and 6B, the opening 116 may be a strip-shaped opening 116 extending along the first horizontal direction hd1. The location of the opening 116 may correspond to the location of a core material of an optical waveguide to be subsequently formed in the intermediate interposer structure 101. It will be understood that other shapes, sizes and directions for the opening 116 in the patterned mask 114 are within the contemplated scope of disclosure. In addition, although FIGS. 6A and 6B illustrate a single strip-shaped opening 116 in the patterned mask 114, it will be understood that the patterned mask 114 may include a plurality of openings 116 through the mask 114.

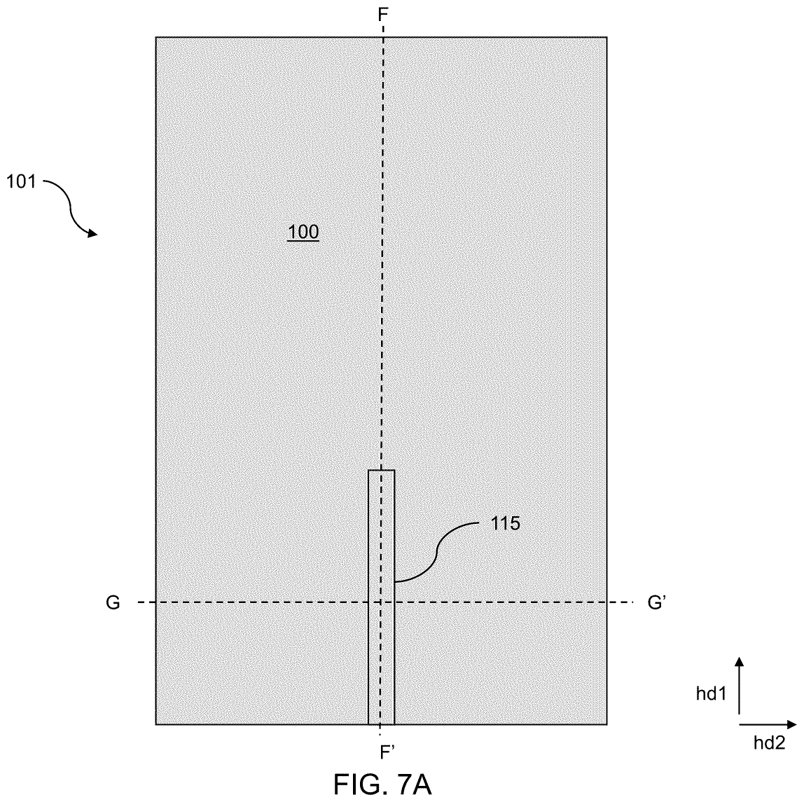

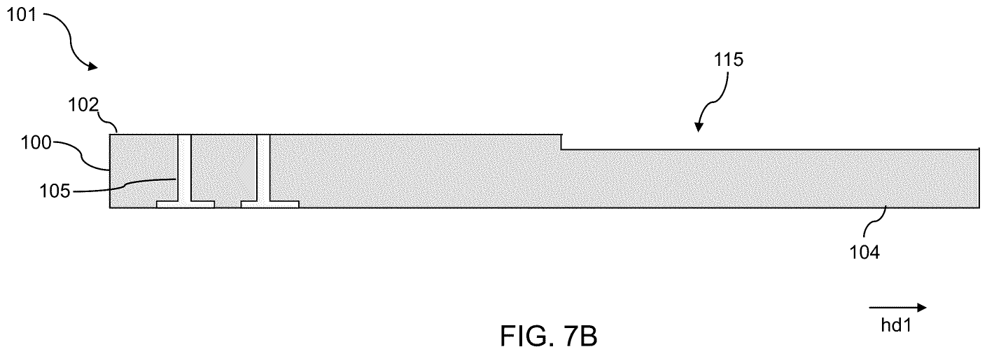

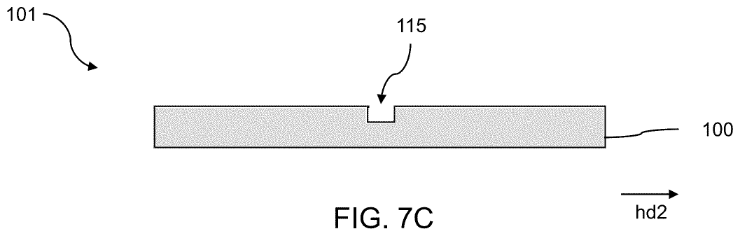

FIG. 7A is a top view of the intermediate interposer structure 101 following an etching process that forms a recess 115 in the first side 102 of the substrate 100 according to various embodiments of the present disclosure. FIG. 7B is a vertical cross-sectional view of the intermediate interposer structure 101 taken along line F-F′ in FIG. 7A. FIG. 7C is a vertical cross-sectional view of the intermediate interposer structure 101 taken along line G-G′ in FIG. 7A. Referring to FIGS. 7A-7C, an etching process may be performed through the patterned mask 114 to remove portions of the substrate 100 that are exposed through the opening 116 in the patterned mask 114. The etching process may form a recess 115 in the first side 102 of the substrate 100. Following the etching process, the patterned mask 114 may be removed using a suitable process, such as via ashing or dissolution using a solvent.

In various embodiments, the recess 115 may include a strip-shape void region in the substrate 100 extending along the first horizontal direction hd1. In some embodiments, the recess 115 may include a generally planar bottom surface that is recessed relative to the first side 102 of the substrate 100. Sidewalls may extend from the bottom surface of the recess 115 to the first side 102 of the substrate 100. In the embodiment shown in FIG. 7C, the sidewalls extend in a vertical direction. However, in other embodiments, the sidewalls of the recess 115 may be angled or curved. Although FIGS. 7A-7C illustrate a recess 115 formed in the substrate 100, it will be understood that a plurality of recesses 115 such as shown in FIGS. 7A-7C, including an interconnected network of recesses 115, may be formed in the substrate 100.

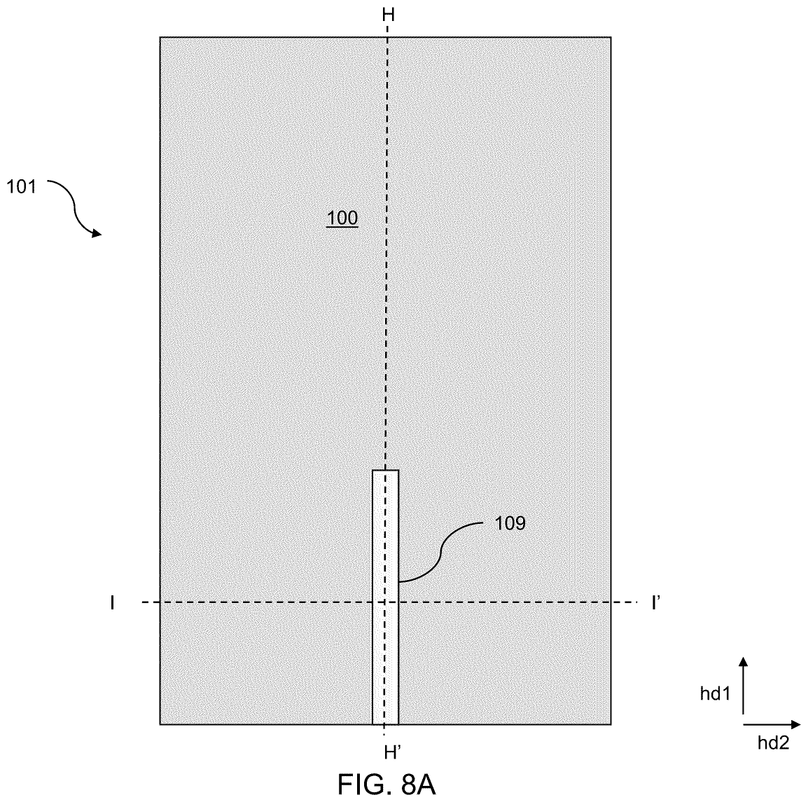

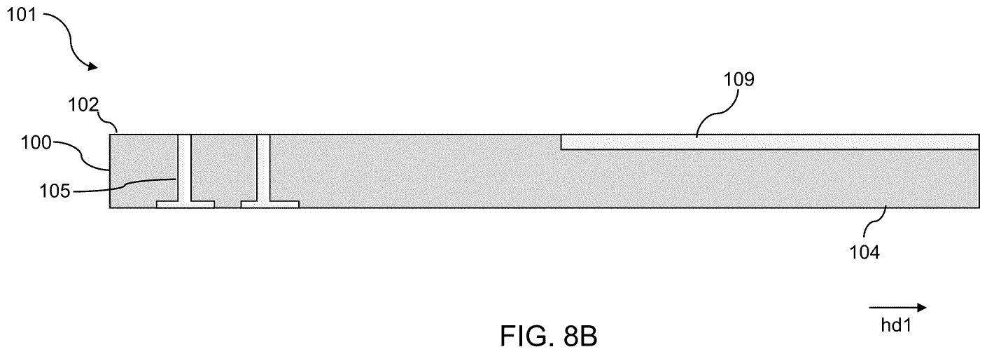

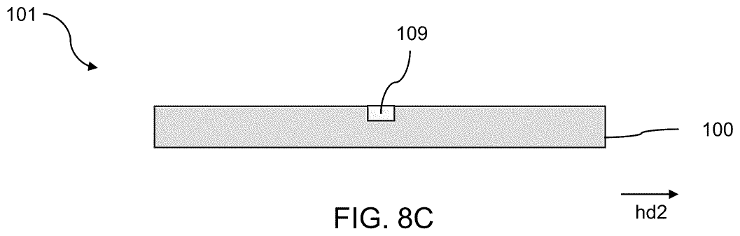

FIG. 8A is a top view of the intermediate interposer structure 101 illustrating a core material 109 formed in the recess 115 in the first side 102 of the substrate 100 according to various embodiments of the present disclosure. FIG. 8B is a vertical cross-sectional view of the intermediate interposer structure 101 taken along line H-H′ in FIG. 8A. FIG. 8C is a vertical cross-sectional view of the intermediate interposer structure 101 taken along line I-I′ in FIG. 8A. Referring to FIGS. 8A-8C, a core material 109 may be deposited within the recess 115 in the first side 102 of the substrate 100. In some embodiments, a continuous layer of core material 109 may be deposited over the first side 102 of the substrate 100 and within the recess 115 using a suitable deposition method as described above. The core material 109 may completely fill the volume of the recess 115. A planarization process, such as a chemical-mechanical planarization (CMP) process, may then be used to remove the core material 109 from over the first side 102 of the substrate 100, leaving a strip-shaped portion of the core material 109 embedded within the substrate 100 and extending along the first horizontal direction hd1. In various embodiments, an upper surface of the core material 109 may be substantially coplanar with the first side 102 of the substrate 100. The bottom surface and side surfaces of the core material 109 may be surrounded by the substrate 100.

Referring again to FIGS. 8A-8C, the core material 109 may include a suitable material such as described above for the core material 109 of FIG. 2. In various embodiments, the core material 109 may have a higher index of refraction than the index of refraction of the surrounding substrate 100. Thus, the substrate 100 may function as a first cladding material (similar to the above-described first cladding material 107 of FIGS. 2-5C) surrounding the bottom surface and side surfaces of the core material 109. In some embodiments, the substrate 100 may include a glass material, and the core material 109 may include a material having a higher index of refraction than the glass material of the substrate 100, such as a semiconductor material (e.g., Si, GaAs, etc.), a dielectric material (e.g., SiN), or the like. Other suitable materials for the substrate 100 and the core material 109 are within the contemplated scope of disclosure. In some embodiments, one or more parameters of the deposition process used to form the core material 109, such as reactant flow ratio(s), pressure, ion source energy, etc., may be controlled to increase the index of refraction of the deposited core material 109.

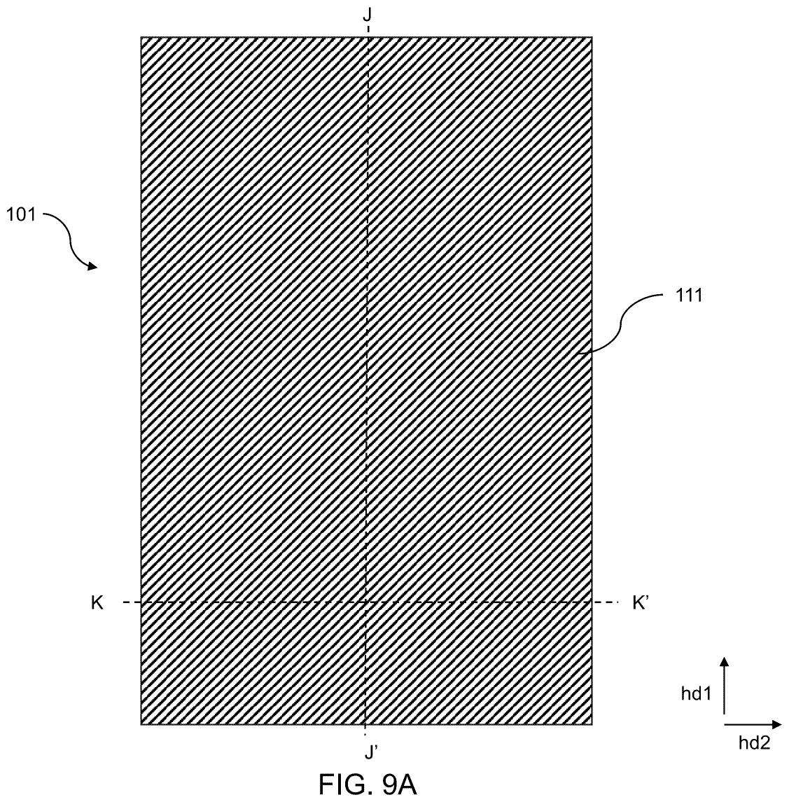

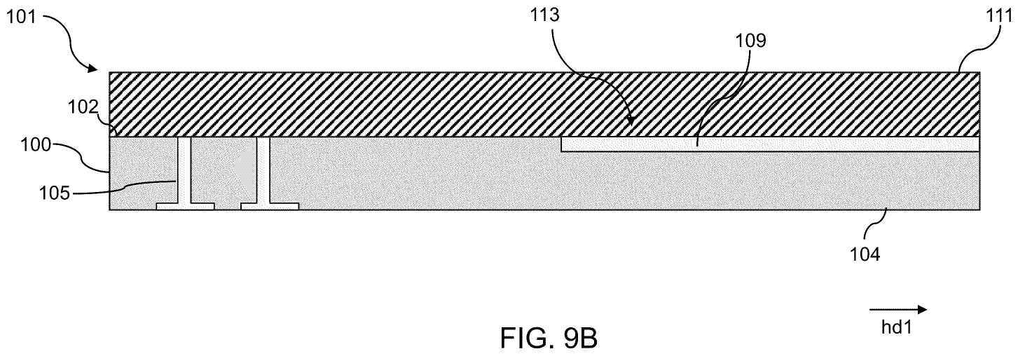

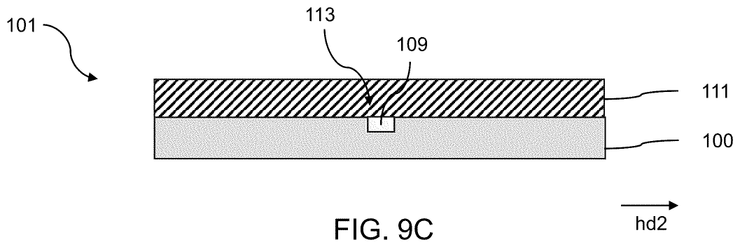

FIG. 9A is a top view of the intermediate interposer structure 101 illustrating a second cladding material 111 formed over the first side 102 of the substrate 100 and the upper surface of the core material 109 according to various embodiments of the present disclosure. FIG. 9B is a vertical cross-sectional view of the intermediate interposer structure 101 taken along line J-J′ in FIG. 9A. FIG. 9C is a vertical cross-sectional view of the intermediate interposer structure 101 taken along line K-K′ in FIG. 9A. Referring to FIGS. 9A-9C, a second cladding material 111 may be deposited over the first side 102 of the substrate 100 and over the upper surface of the core material 109. The second cladding material 111 may be deposited using a suitable deposition process as described above.

The second cladding material 111 may have an index of refraction that is lower than the index of refraction of the core material 109. In various embodiments, the second cladding material 111 may include a suitable dielectric material, such as silicon oxide (SiO₂), silicon nitride (SiN), alumina (Al₂O₃), silica glass (e.g., fluorine-doped silica), a polymer-based dielectric material (e.g., silicone, a fluoropolymer material, etc.), and the like. Other suitable materials for the second cladding material 111 are within the contemplated scope of disclosure.

The second cladding material 111, the core material 109, and the substrate 100 may together form an optical waveguide 113. The optical waveguide 113 may include the core material 109 surrounded on the bottom surface and the side surfaces of the core material 109 by the substrate 100 and on the upper surface of the core material 109 by the second cladding material 111. Thus, the optical waveguide 113 includes a core material 109 that is surrounded on four sides by cladding material 107, 111 having a relatively lower index of refraction than the index of refraction of the core material 109. Accordingly, optical signals (i.e., photons) may propagate through the core material 109 via total internal reflection along the length of the optical waveguide 113 (i.e., along the first horizontal direction hd1 in FIGS. 9A-9C). Although FIGS. 9A-9C illustrate a single optical waveguide 113, it will be understood that a plurality of optical waveguides 113 may be formed in the intermediate interposer structure 101.

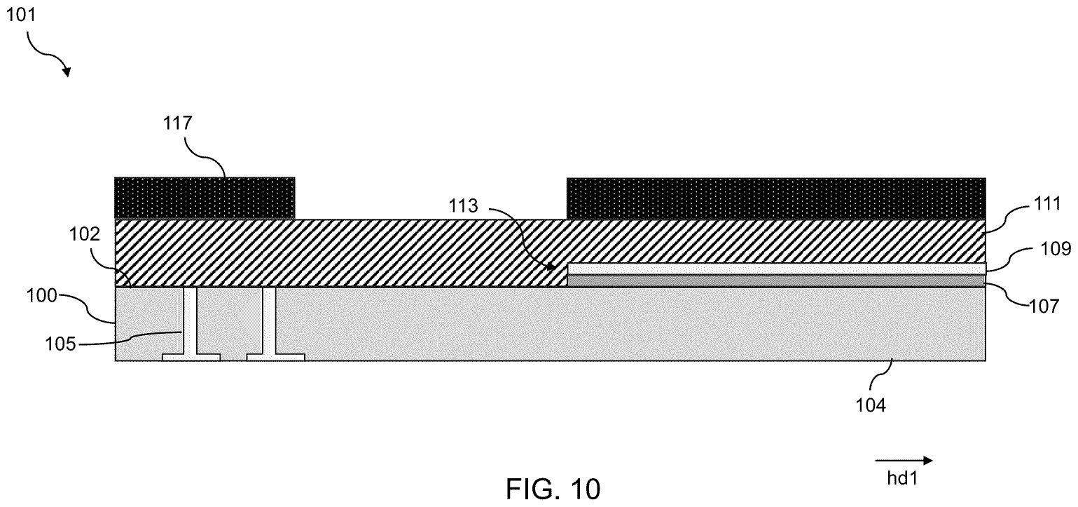

FIGS. 10-14 are sequential vertical cross-sectional views illustrating a process of forming an interposer 160 having an integrated optical waveguide 113 according to various embodiments of the present disclosure. FIG. 10 is a vertical cross-sectional view of an intermediate interposer structure 101 illustrating a patterned mask 117 formed over the upper surface of the second cladding material 111 according to various embodiments of the present disclosure. The intermediate interposer structure 101 shown in FIG. 10 may be similar or identical to the intermediate interposer structure 101 described above with reference to FIGS. 5A-5C. However, a patterned mask 117 as shown in FIG. 10 may also be formed over the second cladding material 111 of an intermediate interposer structure 101 as described above with reference to FIGS. 9A-9C. The patterned mask 117 may be formed by depositing a layer of photoresist material over the upper surface of the second cladding material 111. The layer of photoresist material may be patterned using photolithographic techniques to provide a patterned mask 117 including an opening in the mask 117, where the upper surface of the second cladding material 111 may be exposed through the opening in the mask 117. Although FIG. 10 illustrates an embodiment in which a single opening is formed through the mask 117, in other embodiments more than one opening may be formed in the patterned mask 117.

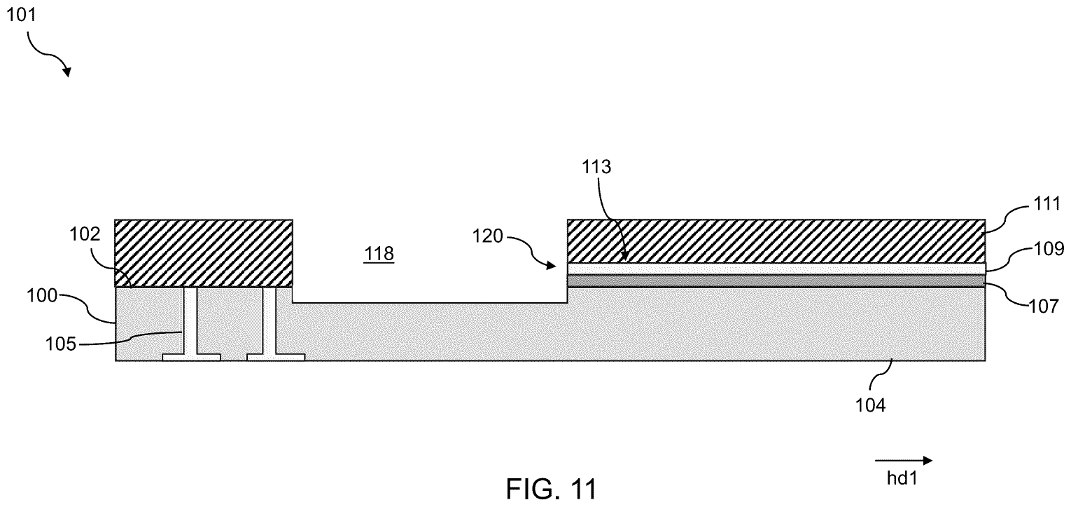

FIG. 11 is a vertical cross-sectional view of an intermediate interposer structure 101 following an etching process that forms a recess 118 through the second cladding material 111 and into the substrate 100 according to various embodiments of the present disclosure. Referring to FIG. 11, an etching process may be performed through the patterned mask 117 to remove portions of the second cladding material 111 exposed through the opening in the patterned mask 117. In some embodiments, the etching process may continue into a portion of the substrate 100. The etching process may form a recess 118. The substrate 100 may be exposed on the bottom surface of the recess 118. In various embodiments, the core material 109 of the optical waveguide 113 may be exposed along a sidewall 120 of the recess 118. In some embodiments, length and width dimensions of the recess 118 (i.e., along the first horizontal direction hd1 and the second horizontal direction hd2) may be at least about 1 mm, such as between about 5 mm and about 20 mm. A horizontal cross-sectional area of the recess 118 may be between about 50 mm² and about 150 mm² (e.g., ˜100 mm²). However, it will be understood that larger and smaller dimensions and areas of the recess 118 are within the contemplated scope of disclosure. Following the etching process, the patterned mask 117 may be removed using a suitable process, such as via ashing or dissolution using a solvent.

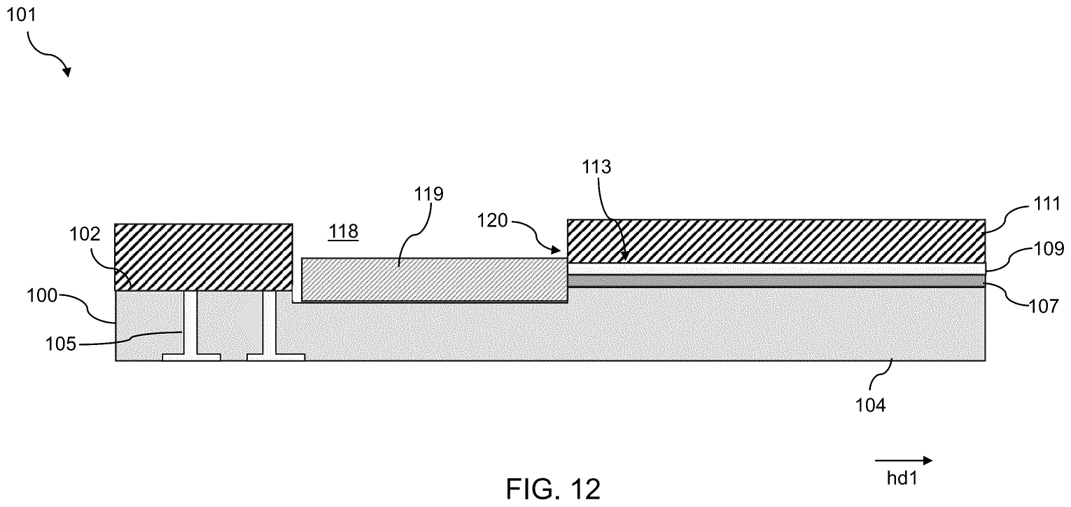

FIG. 12 is a vertical cross-sectional view of an intermediate interposer structure 101 illustrating an integrated circuit (IC) photonic die 119 located in the recess 118 according to various embodiments of the present disclosure. Referring to FIG. 12, an IC photonic die 119 may be provided within the recess 118 of the intermediate interposer structure 101. In some embodiments, the IC photonic die 119 may be placed in the recess 118 using a suitable positioning apparatus (e.g., a pick-and-place tool). In various embodiments, the IC photonic die 119 may include a number of optical components, such as one or more waveguides, lenses, splitters, optical amplifiers, optical modulators, filters, light sources (e.g., laser(s) or LED(s), and/or optical detectors, integrated on a single die or “chip.” The IC photonic die 119 may be optically coupled to the core material 109 of the optical waveguide 113 exposed on the sidewall 120 of the recess 118. In some embodiments, a lens or other optical coupling component (not shown in FIG. 12) may be used to optically couple the core material 109 of the optical waveguide 113 and the IC photonic die 119.

In various embodiments, optical signals (i.e., photons) may be transmitted through the optical waveguide 113 to and/or from the IC photonic die 119 located on the interposer structure 101. In some embodiments, the IC photonic die 119 may include an on-board light source, such as a laser or LED device, that may be used to transmit optical signals from the IC photonic die 119 through the optical waveguide 113 to another photonic component that may be located on and/or external to the interposer structure 101. Alternatively, or in addition, one or more external light sources, which may be located in a different location on the interposer structure 101 and/or external to the interposer structure 101 may be configured to generate optical signals that may be transmitted through the optical waveguide 113 and may be received at the IC photonic die 119.

Although FIG. 12 illustrates an embodiment in which a single IC photonic die 119 is located within a recess 118 of the intermediate interposer structure 101, it will be understood that multiple IC photonic dies 119 may be provided on the intermediate interposer structure 101. Multiple IC photonic dies 119 may be located in the same recess 118 and/or within different recesses 118 of the intermediate interposer structure 101. One or more optical waveguides 113 such as shown in FIG. 12 may provide optical interconnection between different IC photonic dies 119 of the intermediate interposer structure 101.

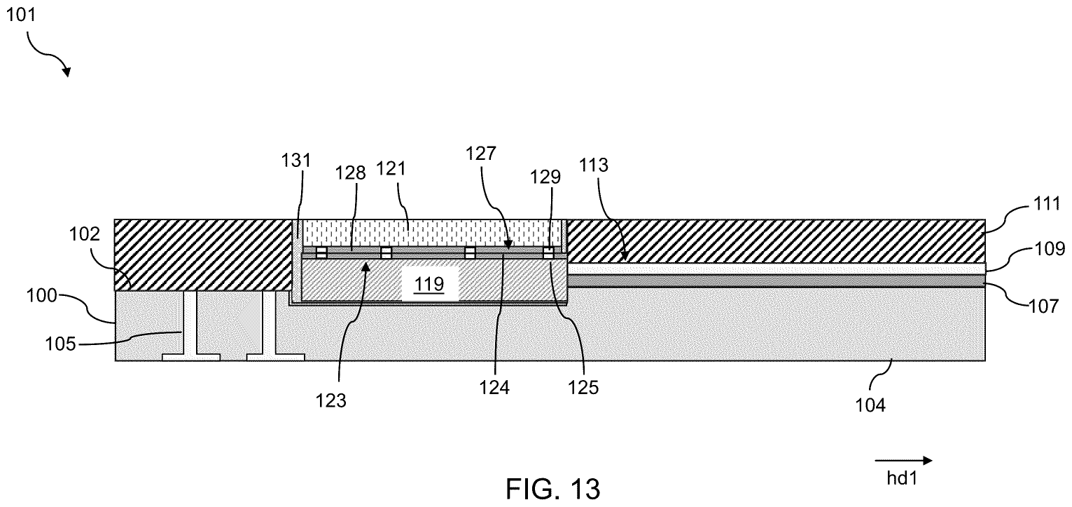

FIG. 13 is a vertical cross-sectional view of an intermediate interposer structure 101 illustrating an IC electronic die 121 located within the recess 118 and bonded to the IC photonic die 119 according to various embodiments of the present disclosure. Referring to FIG. 13, the IC electronic die 121 may include a plurality of electronic circuit components (e.g., transistors, diodes, resistors, capacitors, etc.) integrated on a single die or “chip.” The IC electronic die 121 may be configured to receive, transmit, and/or perform processing operations on electronic signals. In various embodiments, the IC electronic die 121 may be operatively coupled to the IC photonic die 119 such that optical signals at the IC photonic die 119 may be converted to electrical signals that may be further processed and/or transmitted by the IC electronic die 121. For example, optical signals received at one or more detectors (e.g., photodetectors) of the IC photonic die 119 may be converted to electrical signals that may be read-out and optionally further processed (e.g., converted from analog signals to digital signals) by the IC electronic die 121. The IC electronic die 121 may then transmit the electronic signals to one or more other components of the semiconductor package, such as to one or more semiconductor IC dies mounted to the interposer and/or to a package substrate, via conductive interconnect features connected to the IC electronic die 121. Similarly, in some embodiments, IC electronic die 121 may provide electronic signals to the IC photonic die 119 that may be converted to optical signals that may be transmitted from the IC photonic die 119 via one or more optical waveguides 113 to a photonic component, such as another IC photonic die 119, that may be located on or external to the semiconductor package. The IC electronic die 121 may thus be considered as providing an interface between the electronic and photonic components of the semiconductor package.

Referring again to FIG. 13, in various embodiments, a bonding process may be used to bond bonding features on the IC photonic die 119 to corresponding bonding features on the IC electronic die 121. In some embodiments, a direct bonding technique, such as metal-to-metal (M-M) and dielectric-to-dielectric (D-D) bonding technique, may be used to bond the IC photonic die 119 and the IC electronic die 121. In various embodiments, a first bonding layer 123 may be formed over the upper surface of the IC photonic die 119. The first bonding layer 123 may include a first dielectric material 124. The first dielectric material 124 may include, for example, one or more of silicon oxide, silicon nitride, silicon carbide, silicon carbon nitride, silicon oxynitride, a dielectric polymer material, or the like. Other suitable dielectric materials are within the contemplated scope of disclosure. The first dielectric material 124 of the first bonding layer 123 may be deposited using a suitable deposition process as described above. The first dielectric material 124 may have a planar upper surface.

The first bonding layer 123 may also include a plurality of first metal bonding pads 125. The first metal bonding pads 125 may be formed by forming a plurality of openings in the first dielectric material 124 of the first bonding layer 123 and depositing a metal material within the openings, such as via a damascene or dual-damascene process. This may include, for example, performing one or more etching processes through a lithographically-patterned mask to form openings in in the first dielectric material 124, and depositing a suitable metal material within the openings to form the first bonding pads 125. An optional planarization process may be used to remove excess conductive material from over the planar upper surface of the first dielectric material 124. The first bonding pads 125 may include a suitable conductive material, such as copper (Cu), tungsten (W), aluminum (Al), and the like. The first bonding pads 125 may be formed using a suitable deposition process, such as, for example, physical vapor deposition (PVD), sputtering, chemical vapor deposition (CVD), atomic layer deposition (ALD), plasma-enhanced chemical vapor deposition (PECVD), electrochemical deposition (e.g., electroplating), or combinations thereof.

The first metal bonding pads 125 may be laterally surrounded by the first dielectric material 124 of the first bonding layer 123. At least some of the first bonding pads 125 may be electrically coupled to components of the underlying IC photonic die 119 via metal interconnect features.

Referring again to FIG. 13, a second bonding layer 127 may be formed over the lower surface of the IC electronic die 121. The second bonding layer 127 may be similar to the first bonding layer 123 described above, and may include a second dielectric material 128 and a plurality of second bonding pads 129 laterally surrounded by the second dielectric material 128. At least some of the second bonding pads 129 may be electrically coupled to components of the overlying IC electronic die 121 via metal interconnect features. In various embodiments, the layout of the second bonding pads 129 of the second bonding layer 127 may correspond to the layout of the first bonding pads 125 of the first bonding layer 123.

Referring yet again to FIG. 13, a bonding process may be performed to bond the second bonding layer 127 to the first bonding layer 123, and thereby bond the IC electronic die 121 to the IC photonic die 119. In various embodiments, the second bonding layer 127 may be bonded to the first bonding layer 123 via a metal-to-metal (M-M) and dielectric-to-dielectric (D-D) direct bonding technique to couple the IC electronic die 121 mechanically and electrically to the IC photonic die 119. In some embodiments, prior to bonding the IC electronic die 121 to the IC photonic die 119, the surfaces of the first bonding layer 123 on the IC photonic die 119 and/or the second bonding layer 127 on the IC electronic die 121 may optionally be subjected to a pre-treatment process (e.g., a plasma treatment process) to promote surface activation of the first bonding layer 123 and/or the second bonding layer 127. To perform the bonding process, the IC electronic die 121 may be aligned over the IC photonic die 119 using a suitable positioning apparatus, such as a bond head. The IC electronic die 121 may be aligned over the IC photonic die 119 such that second bonding pads 129 of the second bonding layer 127 are aligned with first bonding pads 125 of the first bonding layer 123. The IC electronic die 121 and the IC photonic die 119 may be brought together such that the second bonding layer 127 of the IC electronic die 121 contacts the first bonding layer 123 of the IC photonic die 119. The IC electronic die 121 and the IC photonic die 119 may be aligned such that second bonding pads 129 of the second bonding layer 127 contact corresponding first bonding pads 125 of the first bonding layer 123 and the second dielectric material 128 of the second bonding layer 127 contacts the first dielectric material 124 of the first bonding layer 123.

In a direct bonding process, such as a metal-to-metal (M-M) and dielectric-to-dielectric (D-D) bonding process, bringing the first bonding layer 123 and the second bonding layer 127 into contact with one another may result in a pre-bonding process in which chemical bonds (e.g., hydrogen bridge bonds) may form at the planar interface between the first dielectric material 124 of the first bonding layer 123 and the second dielectric material 128 of the second bonding layer 127. In some embodiments, the pre-bonding process may be performed at ambient temperature (e.g., ˜20° C.). In other embodiments, the pre-bonding process may be performed at an elevated temperature. In some embodiments, a compressive force may be applied to the IC electronic die 121 and the IC photonic die 119 during the pre-bonding process. In other embodiments, no compressive force may be applied during the pre-bonding process.

In some embodiments, an annealing process may be performed to complete the bonding of the first bonding pads 125 of the first bonding layer 123 to the second bonding pads 129 of the second bonding layer 127. The annealing process may be performed at an elevated temperature, such as 100° C. or more, such as between about 150° C. and about 350° C., although lower and higher temperatures may also be utilized. In some embodiments, a compressive force may be applied to the IC electronic die 121 and the IC photonic die 119 during the annealing process. In other embodiments, no compressive force may be applied during the annealing process.

Following the bonding process, the IC electronic die 121 may be mechanically and electronically coupled to the IC photonic die 119. Electrical signals may be transmitted between the IC electronic die 121 and the IC photonic die 119 via the first and second bonding pads 125, 129 of the first and second bonding layers 123, 127. Although FIG. 13 illustrates the IC electronic die 121 bonded to the IC photonic die 119 via a metal-to-metal (M-M) and dielectric-to-dielectric (D-D) direct bonding process, it will be understood that other bonding processes, such as a microbump bonding process, may be used to bond the IC electronic die 121 and the IC photonic die 119.

Referring again to FIG. 13, in some embodiments a gap fill dielectric material 131 may be deposited around and/or over the IC electronic die 121 and the IC photonic die 119 located in the recess 118 of the intermediate interposer structure 101. The gap fill dielectric material 131 may include a suitable dielectric material, such as silicon oxide, silicon nitride, silicon carbide, silicon oxynitride, silicon carbon nitride, a low-K dielectric material, and extremely low-K (ELK) dielectric material, undoped silicon glass (USG), fluorosilicate glass (FSG), phosphor-silicate glass (PSG), etc., including combinations thereof. Other suitable dielectric materials for the gap fill dielectric material 131 are within the contemplated scope of disclosure. The gap fill dielectric material 131 may be deposited using a suitable deposition process as described above. In some embodiments, the gap fill dielectric material 131 may fill a remaining volume of the recess 118 of the intermediate interposer structure 101. In various embodiments, the gap fill dielectric material 131 may laterally surround the IC electronic die 121 around one or more side, including around all sides of the IC electronic die 121. The gap fill dielectric material 131 may laterally surround the IC photonic die 119 around one or more side, including around all sides of the IC photonic die 121, so long as the gap fill dielectric material 131 does not interfere with optical signals transmitted between the IC photonic die 119 and the core material 109 of the optical waveguide 113 exposed on the sidewall 120 of the recess 118. In some embodiments, following the deposition of the gap fill dielectric material 131, a planarization process, such as a CMP process, may be used to remove excess gap fill dielectric material 131 such that the upper surface of the gap fill dielectric material 131 may be substantially coplanar with the upper surface of the second cladding material 111. In the embodiment shown in FIG. 13, the upper surface of the IC electronic die 121 is substantially coplanar with the upper surface of the second cladding material 111. In other embodiments, the upper surface of the IC electronic die 121 may be located above or below the plane of the upper surface of the second cladding material 111. In embodiments in which the upper surface of the IC electronic die 121 is located below the plane of the upper surface of the second cladding material 111, the gap fill dielectric material 131 may extend over the upper surface of the IC electronic die 121.

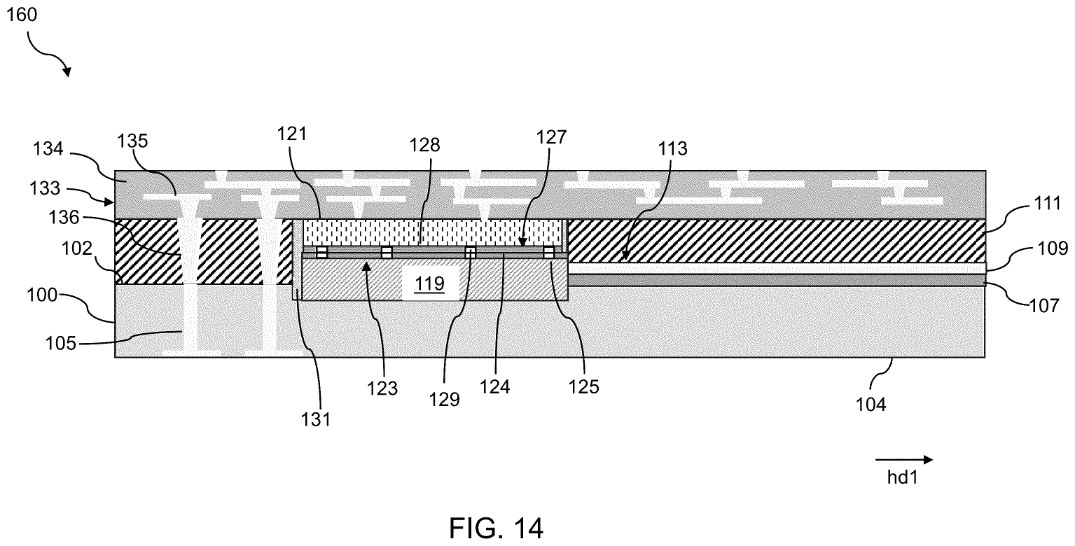

FIG. 14 is a vertical cross-sectional view of an interposer 160 including a redistribution structure 133 according to various embodiments of the present disclosure. Referring to FIG. 14, a redistribution structure 133 including metal interconnect features 135 formed within a dielectric material matrix 134 may be formed over the upper surface of the second cladding material 111, over the upper surface of the gap fill dielectric material 131, and over the upper surface of the IC electronic die 121. In some embodiments, additional metal interconnect features 136 may be formed within the second cladding material 111 and optionally within the first cladding material 107. The metal interconnect features 136 formed within the cladding material 111, 107 may be electrically coupled to through-substrate vias 105 extending through the substrate 100 of the interposer 160. The metal interconnect features 135 of the redistribution structure 133 may be electrically coupled to the IC electronic die 121. In various embodiments, the metal interconnect features 135 and 136 within the cladding material 111, 107 and/or the redistribution structure 133 may provide electrical interconnections between the through-substrate vias 105 and the IC electronic die 121 of the interposer 160 and semiconductor dies that may be subsequently mounted to the interposer 160 as described in further detail below.

In various embodiments, the metal interconnect features 136 through the second cladding material 111 and optionally the first cladding material 107 may be formed by performing one or more etching processes through a lithographically-patterned mask to form openings in in the second cladding material 111 and optionally the first cladding material 107, and depositing a suitable metal material within the openings to form the metal interconnect features 135. The redistribution structure 133 may be formed by depositing one or more layers of a dielectric material over the upper surface of the second cladding material 111, over the upper surface of the gap fill dielectric material 131, and over the upper surface of the IC electronic die 121, performing an etching process through a lithographically-patterned mask to form openings in each layer of dielectric material, and depositing a suitable metal material within the openings to form metal interconnect features 135, such as metal lines and vias.

The dielectric material matrix 134 of the redistribution structure 133 may include any suitable dielectric material, such as silicon oxide, silicon nitride, silicon carbide, silicon oxynitride, silicon carbon nitride, a low-K dielectric material, and extremely low-K (ELK) dielectric material, undoped silicon glass (USG), fluorosilicate glass (FSG), phosphor-silicate glass (PSG), a polymer-based dielectric material (e.g., polyimide (PI), epoxy resin, polybenzoxazole (PBO)), etc., including combinations thereof. Other suitable materials for the dielectric material matrix 134 are within the contemplated scope of disclosure. The metal interconnect features 135 and 136 may include any suitable metals, metal alloys, and/or other metal-containing compounds (e.g., Cu, Al, Ni, Mo, Co, Ru, Ti, Ta, W, TiN, TaN, WN, etc.). Other suitable metal materials are within the contemplated scope of disclosure. The dielectric material matrix 134 and the metal interconnect features 135 and 136 may be formed using suitable deposition methods as described above.

Although FIG. 14 illustrates a redistribution structure 133 formed over the first side 102 of the substrate 100, in some embodiments, an additional redistribution structure may also be formed over the second side 104 of the substrate 100.

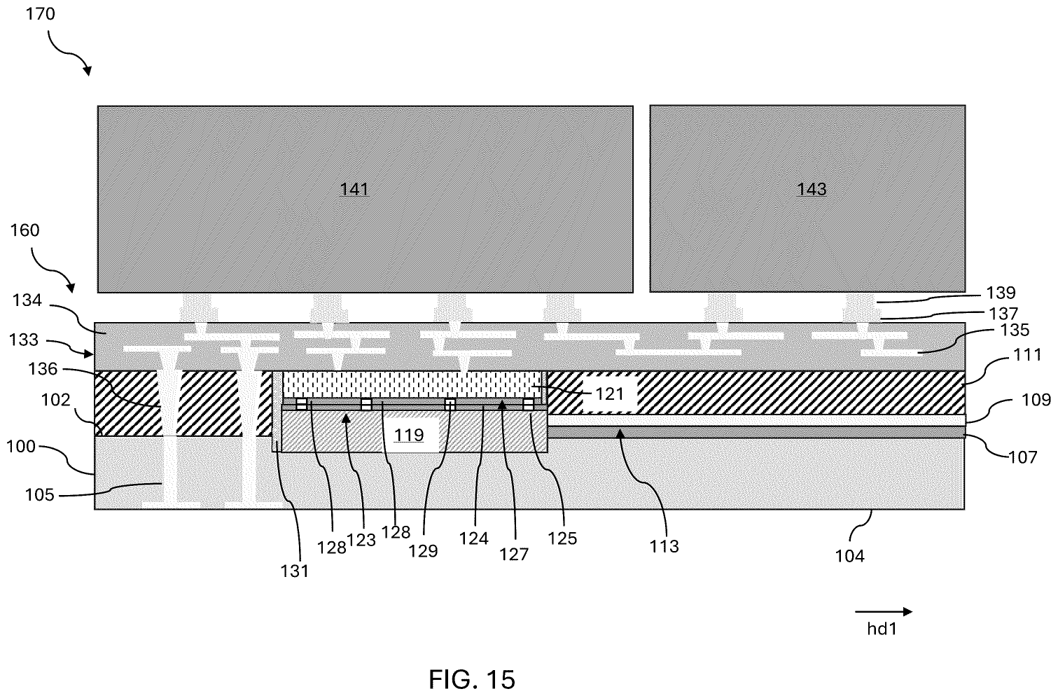

FIG. 15 is a vertical cross-sectional view of a package structure 170 including a first semiconductor die 141 and a second semiconductor die 143 mounted to the interposer 160 according to various embodiments of the present disclosure. Referring to FIG. 15, a semiconductor package structure 170 may include a plurality of integrated circuit (IC) semiconductor dies, such as a first semiconductor die 141 and a second semiconductor die 143, mounted to a common interposer 160. Although FIG. 15 illustrates a semiconductor package structure 170 two IC semiconductor dies 141 and 143 mounted to the interposer 160, it will be understood that a semiconductor package structure 170 may include a greater or lesser number of IC semiconductor dies 141, 143 mounted to the interposer 160.

In some embodiments, the first semiconductor die 141 may be three-dimensional device, such as a three-dimensional integrated circuit (3DICs), a System on Chip (SOC) or a System on Integrated Circuit (SoIC) device. A three-dimensional semiconductor device may be formed by placing chips over chips on a semiconductor wafer level. These three-dimensional devices may provide improved integration density and other advantages, such as faster speeds and higher bandwidths, due to a decreased length of interconnects between the stacked chips. In some embodiments, a first three-dimensional semiconductor device may also be referred to as a “first die stack.” In some embodiments, the first semiconductor die 141 may include one or more “core” devices, such as processor or “logic” die (e.g., a CPU die, a GPU die, an ASIC die, etc.).

In some embodiments, the second semiconductor die 143 may be different from the first semiconductor die 141 in terms of its structure, design and/or functionality. The second semiconductor die 143 may be a three-dimensional semiconductor die, which may also be referred to as a “second die stack.” In some embodiments, the second semiconductor die 143 may include a memory device, such as a high bandwidth memory (HBM) device or another suitable memory device. However, it will be understood that the first semiconductor die 141 and the second semiconductor die 143 can include any suitable type(s) of IC semiconductor dies.

Referring again to FIG. 15, the first semiconductor die 141 and the second semiconductor die 143 may be mounted to the interposer 160 by a plurality of first bonding structures 137 located on the interposer 160 and a plurality of second bonding structures 139 located on the semiconductor dies 141 and 143. In one embodiment, the first bonding structures 137 may include a plurality of bonding pads located on an upper surface of the interposer 160. In the embodiment of FIG. 15, the first bonding structures 137 include bonding pads formed over the upper surface of the redistribution structure 133 of the interposer 160. Each bonding pad may be electrically connected to a metal interconnect feature 135 of the underlying redistribution structure 133. The second bonding structures 139 may include a plurality of metal bumps, such as microbumps, located on the bottom surfaces of the first semiconductor die 141 and the second semiconductor die 143. In some embodiments, each of the metal bumps may include a metal stack, such as a Cu—Ni—Cu stack, formed on the bottom surface of the first semiconductor die 141 or the second semiconductor die 143. In some embodiments, the bonding pads formed on the upper surface of the interposer 160 may also include a metal stack, such as a Cu—Ni—Cu stack. A solder material, such as tin-based solder material, may be located between respective first bonding structures 137 and second bonding structures 139 to electrically connect the first semiconductor die 141 and the second semiconductor die 143 to the interposer 160. Other suitable bonding methods and bonding structures for bonding the first semiconductor die 141 and the second semiconductor die 143 to the interposer 160 are within the contemplated scope of disclosure.

In some embodiments, an underfill material (not shown in FIG. 15) may be provided between the upper surface of the interposer 160 and the lower surfaces of the first semiconductor die 141 and the second semiconductor die 143 and laterally surrounding the first bonding structures 137 and the second bonding structures 139. In some embodiments, the underfill material may also be provided in the space laterally separating the first semiconductor die 141 and the second semiconductor die 143. The underfill material may include, for example, an epoxy-based material, such as a composite material including resin and filler material(s).

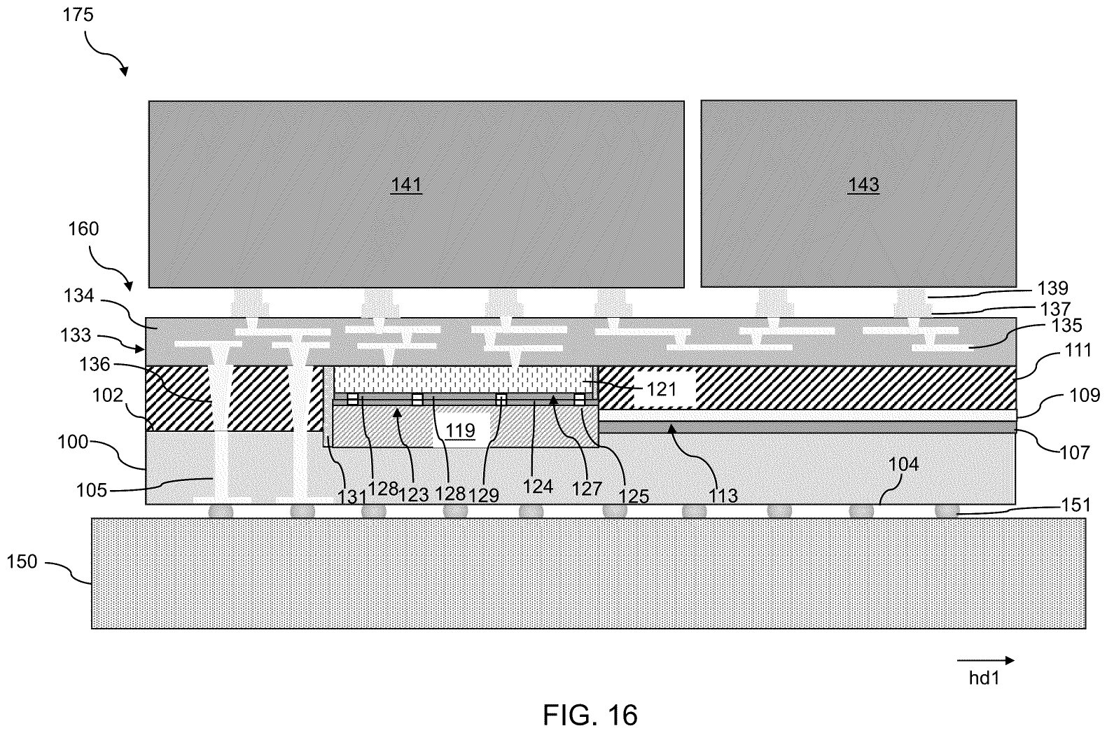

FIG. 16 is a vertical cross-sectional view of a semiconductor package 175 including a package structure 170 having an interposer 160 with a plurality of semiconductor dies 141, 143 located thereon mounted to a package substrate 150 according to various embodiments of the present disclosure. Referring to FIG. 16, the interposer 160 may be mounted onto a package substrate 150 that may provide mechanical support for the interposer 160 and the semiconductor dies 141, 143 that are mounted on the interposer 160. In various embodiments, the package substrate 150 may include a suitable material, such as an organic material (e.g., a polymer and/or thermoplastic material), a semiconductor material (e.g., a semiconductor wafer, such as a silicon wafer), a ceramic material, a glass material, combinations thereof, etc. Other suitable substrate materials are within the contemplated scope of the present disclosure. In various embodiments, the package substrate 150 may include a plurality of conductive bonding pads (not shown) in an upper surface of the package substrate 150. A plurality of bonding material portions 151, such as C4 solder bumps, may electrically connect conductive bonding pads (not shown) on the bottom surface of the interposer 160 to the conductive bonding pads on the upper surface of the package substrate 150. In various embodiments, the bonding material portions 151 may include a suitable solder material, such as a tin-based solder material. although other suitable materials for the bonding material portions 151 are within the contemplated scope of disclosure.

In some embodiments, an underfill material (not shown in FIG. 16) may be provided between the upper surface of the package substrate 150 and the lower surface of the interposer 160 and surrounding the bonding material portions 151. The underfill material may include, for example, an epoxy-based material, such as a composite material including resin and filler material(s). In some embodiments, one or more additional components, such as a stiffening ring and/or a lid or cover (not shown in FIG. 16) may be mounted to the upper surface of the package substrate 100 and may provide an enclosure around at least a portion of the interposer 160 and the semiconductor dies 141 and 143.

In various embodiments, the package substrate 150 may include a plurality of conductive interconnect features (not shown in FIG. 16) extending between the bonding pads on the upper surface of the package substrate 150 and a plurality of bonding pads on the lower surface of the package substrate 150. In some embodiments, the semiconductor package 170 may be mounted to a support structure, such as a printed circuit board (PCB), by mounting the package substrate 150 to the support structure using an array of solder balls contacting the bonding pads on the lower surface of the package substrate 150.

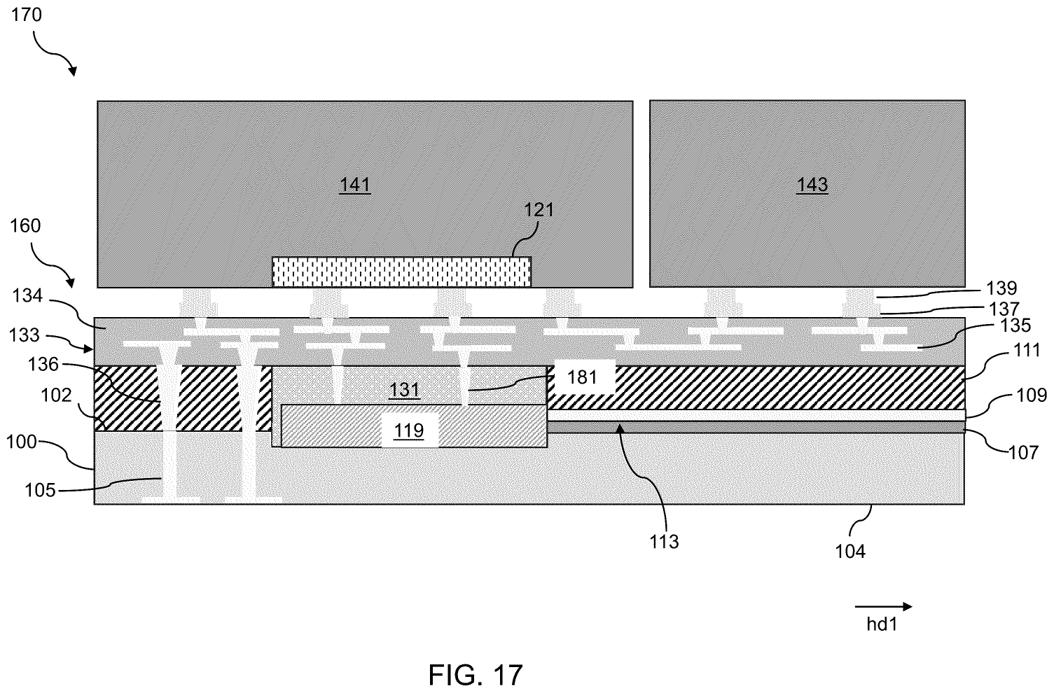

FIG. 17 is a vertical cross-sectional view illustrating a package structure 170 according to another embodiment of the present disclosure. The package structure 170 shown in FIG. 17 may be similar to the package structure 170 shown in FIG. 15, and may include a first semiconductor die 141 and a second semiconductor die 143 mounted to an interposer 160 that includes an integrated IC photonic die 119 and an optical waveguide 113. Thus, repeated discussion of like features is omitted for brevity. The package structure 170 shown in FIG. 17 differs from the package structure 170 of FIG. 15 in that the IC electronic die 121 is not located on the interposer 160. Rather, the IC electronic die 121 may be mounted over the upper surface of the interposer 160 with the first semiconductor die 141 and the second semiconductor die 143. In some embodiments, the IC electronic die 121 may be monolithically formed on the first semiconductor die 141, which may include a “core” device as described above. In other embodiments, the IC electronic die 121 may be a separate die that may be bonded to the first semiconductor die 141 via a direct bonding or other bonding technique.

Referring again to FIG. 17, the IC photonic die 119 may be located in a recess formed in the interposer 160 and may be optically coupled to the optical waveguide 113. The gap fill dielectric material 131 may fill the remaining volume of the recess and may be located over the upper surface of the IC photonic die 119. Metal interconnect features 181 may extend through the gap fill dielectric material 131 and may be electrically coupled to the IC photonic die 119. Electrical signals between the IC photonic die 119 of the interposer 160 and the IC electronic die 121 mounted over the interposer may be transmitted via the metal interconnect features 181 in the gap fill dielectric material 131, the metal interconnect features 135 in the redistribution structure 133, and the first and second bonding structures 137, 139 that bond the first semiconductor die 141 to the interposer 160. The package structure 170 shown in FIG. 17 may be subsequently mounted to a package substrate to form a semiconductor package 175 as described above with reference to FIG. 16.

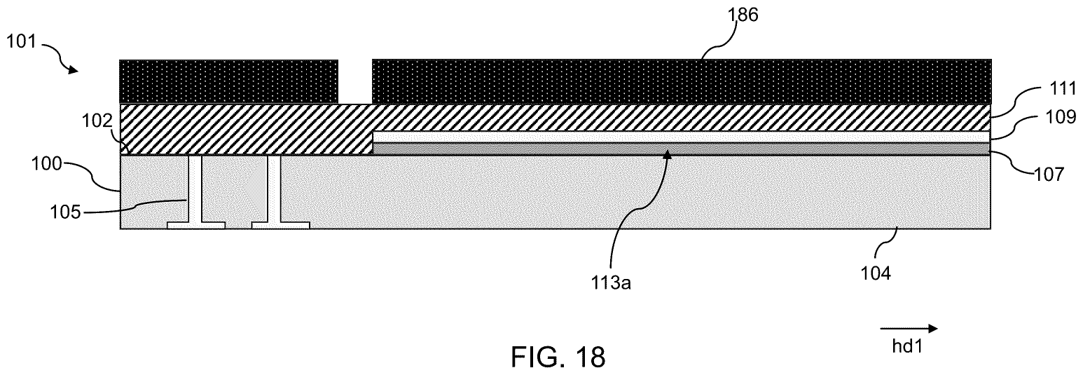

FIGS. 18-22 are sequential vertical-cross section views illustrating a method of forming a package structure 170 including an interposer 160 having integrated photonic components according to another embodiment of the present disclosure. FIG. 18 is a vertical cross-sectional view of an intermediate interposer structure 101 including a patterned mask 186 over an upper surface of a second cladding layer 111 according to various embodiments of the present disclosure. Referring to FIG. 18, the intermediate interposer structure 101 of FIG. 18 may be similar to the intermediate interposer 101 described above with reference to FIGS. 5A-5C. Thus, repeated discussion of like features is omitted for brevity. The intermediate interposer structure 101 may include a first optical waveguide segment 113a. The first optical waveguide segment 113a may include a core material 109 extending along a first horizontal direction hd1 and surrounded on four sides by a cladding material 107, 111. In this embodiment, the cladding material includes a first cladding material 107 on a bottom surface of the core material 109 and a second cladding material 111 on side surfaces and over an upper surface of the core material 109. In other embodiments, the core material 109 may be embedded in the substrate 100 of the intermediate interposer structure 101 such that the substrate 100 may function as a first cladding material on the bottom surfaces and sidewalls of the core material 109, and the second cladding material 111 may be located over the upper surface of the core material 109, such as described above with reference to FIGS. 9A-9C.

Referring again to FIG. 18, a patterned mask 186 may be formed over the upper surface of the second cladding material 111. The patterned mask 186 may be formed by depositing a layer of photoresist material over the upper surface of the second cladding material 111. The layer of photoresist material may be patterned using photolithographic techniques to provide a patterned mask 186 including an opening in the mask 186, where the upper surface of the second cladding material 111 may be exposed through the opening in the mask 186.

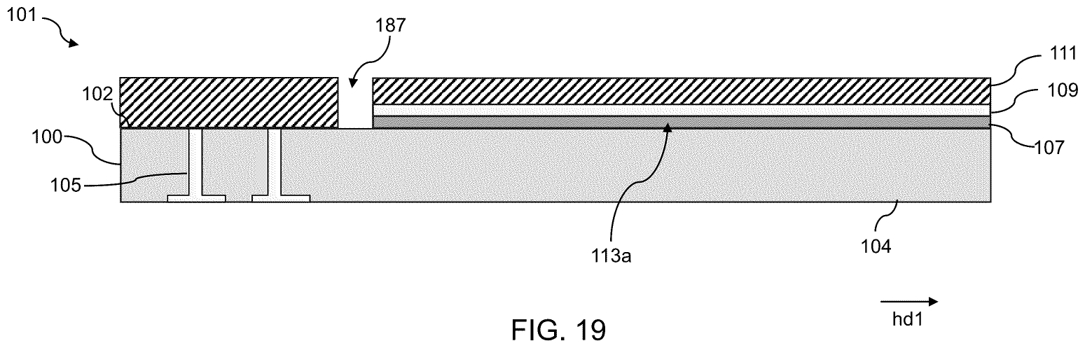

FIG. 19 is a vertical cross-sectional view of an intermediate interposer structure 101 following an etching process that forms an opening 187 in the second cladding material 111 according to various embodiments of the present disclosure. Referring to FIG. 19, an etching process may be performed through the patterned mask 186 to remove portions of the second cladding material 111 exposed through the opening in the patterned mask 186. The etching process may form an opening 187 in the second cladding material 111. In various embodiments, the core material 109 of the first optical waveguide segment 113a may be exposed along a sidewall of the opening 187. Following the etching process, the patterned mask 186 may be removed using a suitable process, such as via ashing or dissolution using a solvent.

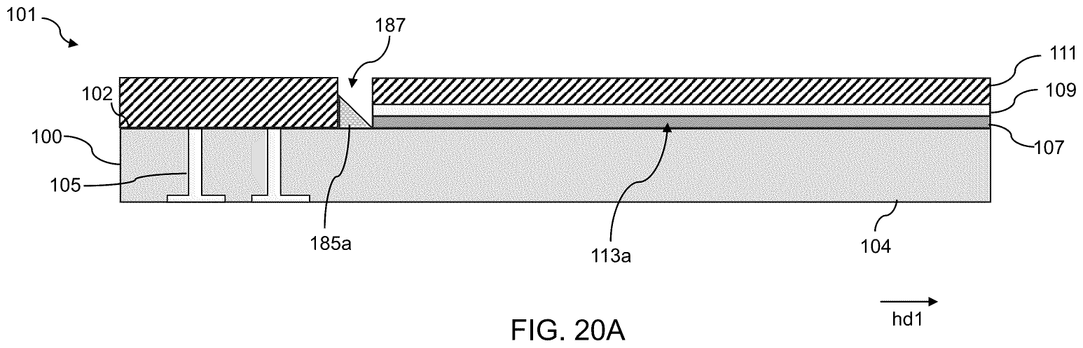

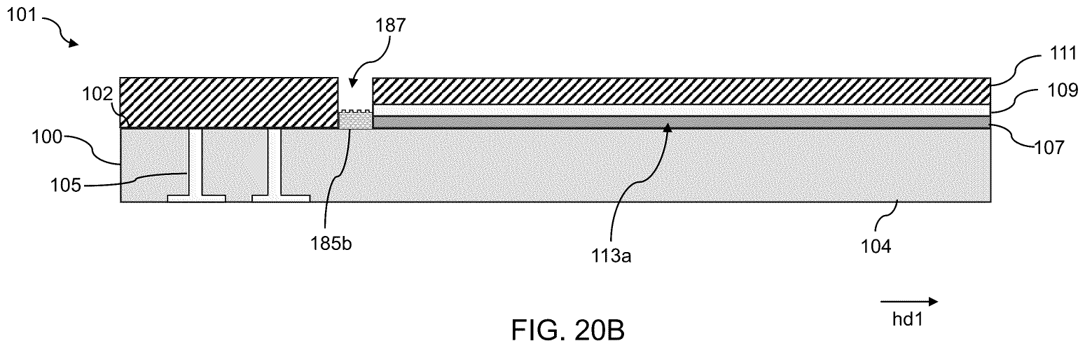

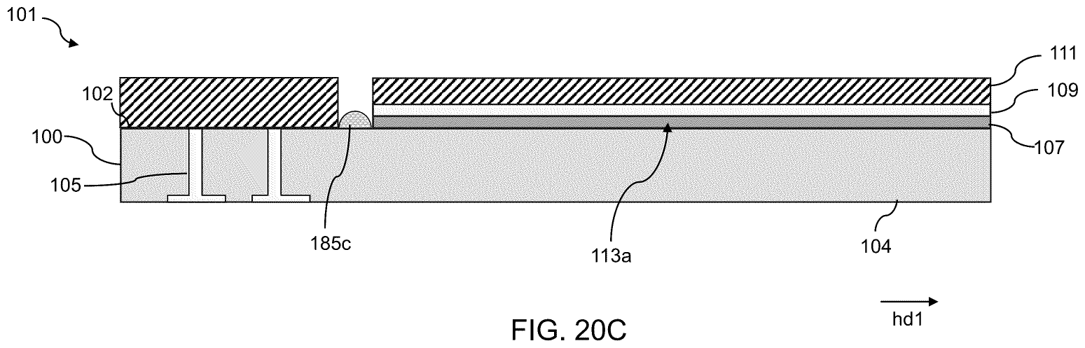

FIGS. 20A-20C are vertical cross section views of an intermediate interposer structure 101 including optical components 185a, 185b and 185c located in the opening 187 in the second cladding material 187 according to various embodiments of the present disclosure. Referring to FIGS. 20A-20C, the optical components 185a, 185b and 185c (which may be collectively referred to as “optical component 185) may be provided within the opening 187 in the second cladding material 187. The optical component 185 may be configured to change a direction of optical signals (i.e., photons) that impinge on the optical component 185. For example, the optical component 185 may be configured to change a direction of photons transmitted within the core material 109 of the first optical waveguide segment 113a from a substantially horizontal direction (i.e., along hd1) to a substantially vertical direction. In various embodiments, the optical component 185 may be configured to change the direction of photon travel based on the geometric and/or material properties (e.g., index of refraction) of the optical component 185. FIG. 20A illustrates a first exemplary embodiment in which the optical component 185 includes a triangular shaped mirror 185a configured to redirect optical signals from a substantially horizontal direction to a substantially vertical direction, and vice versa. FIG. 20B illustrates a second exemplary embodiment in which the optical component 185 includes a grating 185b that may be configured to change the direction of optical signal propagation (e.g., between a horizontal and a vertical direction and/or between a vertical direction and a horizontal direction). FIG. 20C illustrates a third exemplary embodiment in which the optical component 185 includes a bubble-shaped element having a curved surface and including an index of refraction configured to change the direction of optical signal propagation (e.g., between a horizontal and a vertical direction and/or between a vertical direction and a horizontal direction). Other suitable optical components 185 for changing the direction of optical signal propagation may also be utilized.

In some embodiments, the optical components 185a, 185b and 185c as shown in FIGS. 20A-20C may be fabricated separately and placed within the opening 187 using a suitable placement apparatus (e.g., a pick-and-place tool). In other embodiments, the optical components 185a, 185b and 185c may be manufactured in-situ within the opening 187.

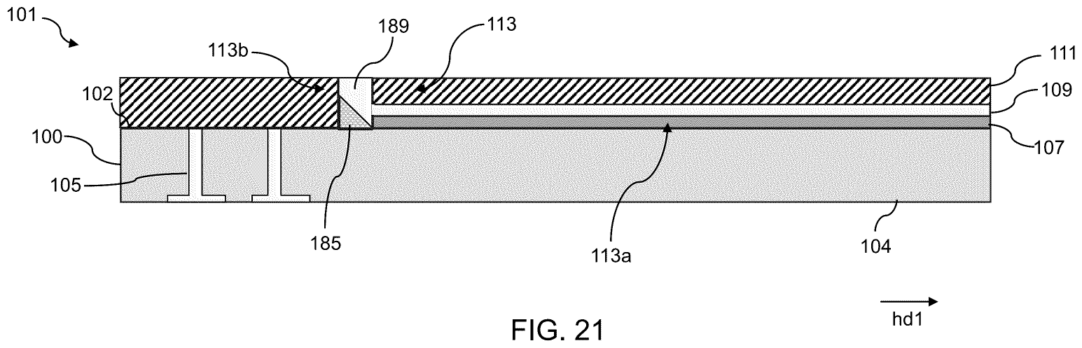

FIG. 21 is a vertical cross-sectional view of an intermediate interposer structure 101 including a second core material 189 within the opening 187 in the second cladding material 111 according to various embodiments of the present disclosure. Referring to FIG. 21, a second core material 189 may be deposited over the intermediate interposer structure 101 including with the opening 187 in the second cladding material 111. In various embodiments, the second core material 189 may be formed over the optical component 185 located within the opening 187 and may contact the core material 109 exposed along the sidewall of the opening 187. The second core material 189 may fill the remaining volume of the opening 187. In some embodiments, a planarization process, such as a CMP process, may be performed to remove the second core material 189 from over the upper surface of the second cladding layer 111.

The second core material 189 may include a suitable material such as described above for the core material 109 of FIG. 2. In some embodiments, the second core material 189 may include the same composition as the core material 109. Alternatively, the second core material 189 and the core material 189 may have different compositions. In various embodiments, the second core material 189 may have a higher index of refraction than the index of refraction of the second cladding layer 111 that laterally surrounds the second core material 189. Thus, the second core material 189 and the second cladding layer 111 laterally surrounding the second core material 189 may form a second optical waveguide segment 113b. The second optical waveguide segment 113b may be continuous with the first optical waveguide segment 113a, and the second optical waveguide segment 113b together with the first optical waveguide segment 113a may form an optical waveguide 113. The first optical waveguide segment 113a of the optical waveguide 113 may direct optical signals along a first direction (i.e., a horizontal direction) and the second optical waveguide segment 113b of the optical waveguide 113 may direct optical signals along a second direction (i.e., a vertical direction) that is orthogonal to the first direction.

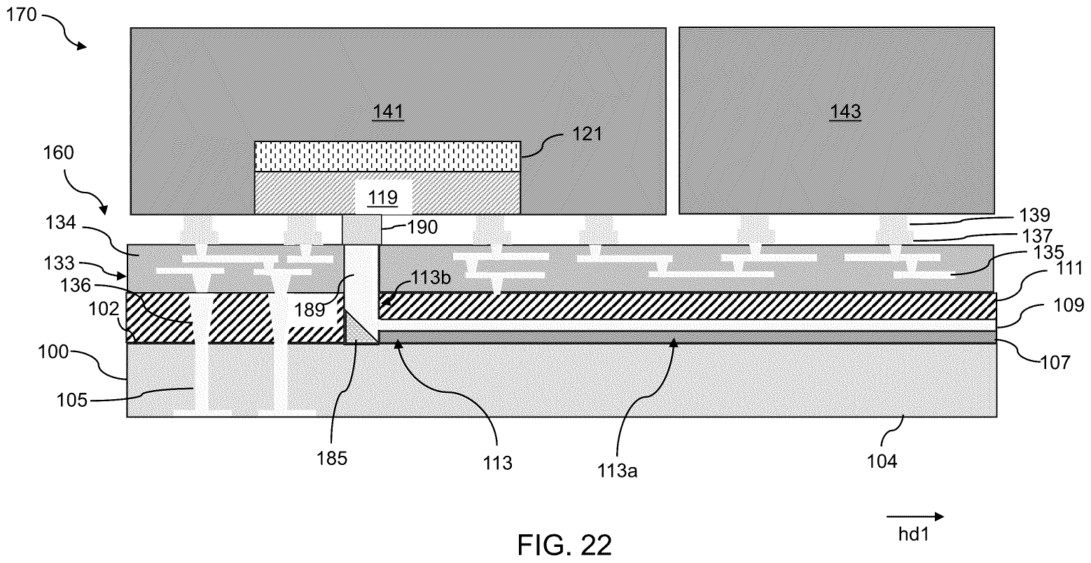

FIG. 22 is a vertical cross-sectional view of a package structure 170 according to various embodiments of the present disclosure. Referring to FIG. 22, the package structure 170 may be similar to the package structures 170 shown in FIGS. 15 and 17. In particular, the package structure 170 of FIG. 22 may include a first semiconductor die 141 and a second semiconductor die 143 mounted to an interposer 160 including an integrated optical waveguide 113. Thus, repeated discussion of like features is omitted for brevity. The package structure 170 shown in FIG. 22 differs from the package structures 170 of FIGS. 15 and 17 and in that both the IC photonic die 119 and the IC electronic die 121 are not located on the interposer 160. Rather, the IC photonic die 119 and the IC electronic die 121 may be mounted over the upper surface of the interposer 160 with the first semiconductor die 141 and the second semiconductor die 143. Thus, electrical interconnections between the IC photonic die 119 and the IC electronic die 121 may occur within the first semiconductor die 141. In addition, the interposer 160 may include an integrated optical waveguide 113 that includes a first optical waveguide segment 113a that directs optical signals along a first direction (i.e., a horizontal direction) and a second optical waveguide segment 113b that directs optical signals along a second direction (i.e., a vertical direction). A optical component 185 as described above with reference to FIGS. 20A-20C may redirect optical signals between the first optical waveguide segment 113a and the second optical waveguide segment 113b.

In various embodiments, the second optical waveguide segment 113b as shown in FIG. 21 may be extended through the redistribution structure 133 to the upper surface of the interposer 160 as shown in FIG. 22. This may include, for example, forming an opening through the dielectric material matrix 134 of the redistribution structure 133 (e.g., via performing an etching process through a patterned mask) and depositing additional second core material 189 within the opening. In various embodiments, the additional second core material 189 may have a higher index of refraction than the surrounding material of the dielectric material matrix 134. The second optical waveguide segment 113b extending in a vertical direction from the upper surface of the interposer 160 may also be referred to as an “optical via.” In various embodiments, the first semiconductor die 141 may be mounted to the interposer 160 such that the IC photonic die 119 may be located above the second optical waveguide segment 113b (i.e., optical via) of the optical waveguide 113. In some embodiments, an optical coupling material 190 may be provided within the gap between the upper surface of the interposer and the lower surface of the first semiconductor die 141 including the IC photonic die 119. The optical coupling material 190 may be substantially transparent to the optical signals transmitted through the optical waveguide 113. Optical signals transmitted between the IC photonic die 119 and the optical waveguide 113 may be transmitted through the optical coupling material 190 in various embodiments. In one non-limiting embodiment, the optical coupling material 190 may include a suitable dielectric material, such as silicon oxide. Other suitable materials for the optical coupling material 190 are within the contemplated scope of disclosure. The optical coupling material 190 may be formed between adjacent first bonding structures 137 used to transmit electric signals between the semiconductor dies 141, 143 and the interposer 160. In some embodiments, the optical coupling material 190 may be laterally surrounded by an above-described underflow material.

Referring again to FIG. 22, in some embodiments, the IC photonic die 119 and the IC electronic die 121 may be vertically-stacked. In some embodiments, IC photonic die 119 and the IC electronic die 121 may be bonded to one another using a suitable bonding process, such as a direct bonding process as described above with reference to FIG. 13. In some embodiments, the IC photonic die 119 and/or the IC electronic die 121 may be monolithically formed on the first semiconductor die 141, which may include a “core” device as described above. In other embodiments, the IC photonic die and/or the IC electronic die 121 may be separate die(s) that may be bonded to the first semiconductor die 141 via a direct bonding or other bonding technique.

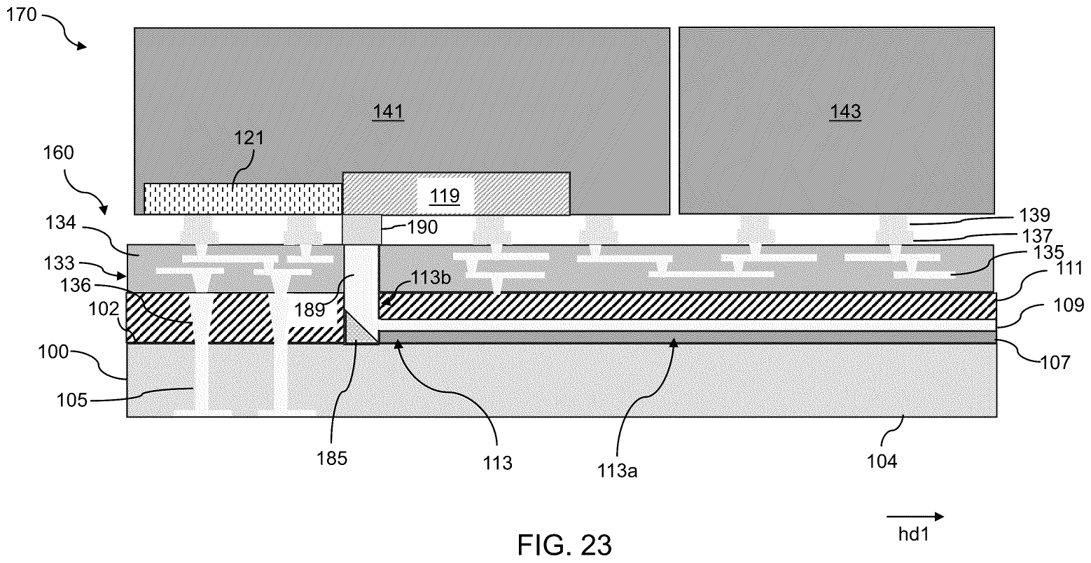

FIG. 23 is a vertical cross-sectional view of a package structure 170 according to another embodiment of the present disclosure. The package structure 170 of FIG. 23 is similar to the package structure 170 of FIG. 22, except that in the embodiment of FIG. 23, the IC photonic die 119 and the IC electronic die 121 are arranged side-by-side rather than vertically-stacked as shown in FIG. 22.

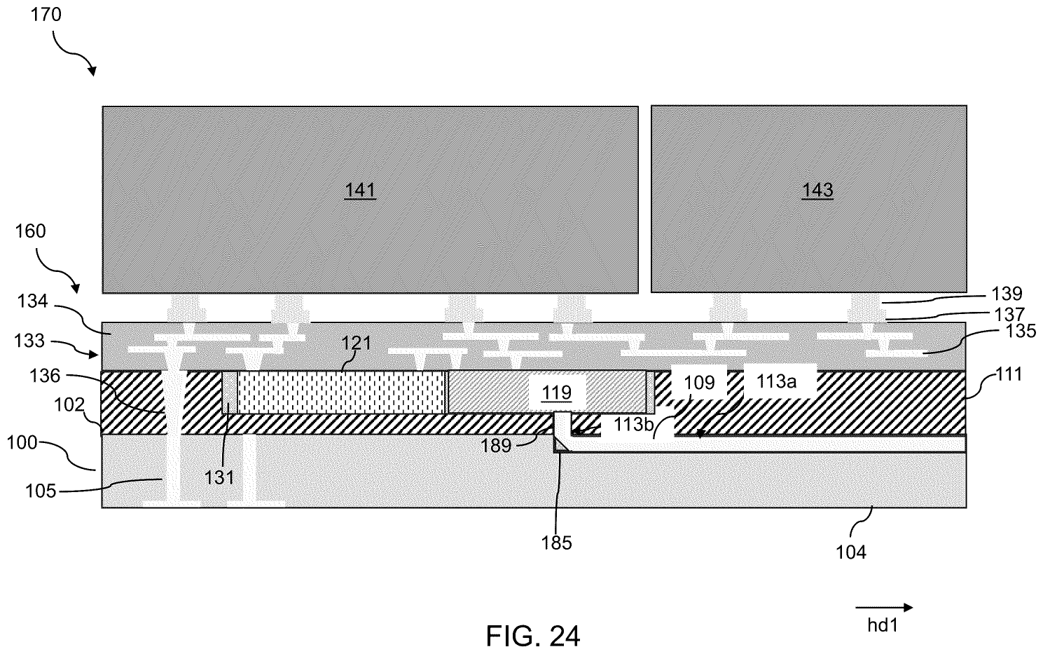

FIG. 24 is a vertical cross-sectional view of a package structure 170 according to another embodiment of the present disclosure. The package structure 170 of FIG. 24 is similar to the package structure 170 described above with reference to FIG. 15 in that the interposer 160 includes an IC photonic die 119 and an IC electronic die 121. The IC photonic die 119 and the IC electronic die 121 may both be provided in a recess 118 in the interposer 160 (see FIGS. 11-13). In the embodiment of FIG. 24, the IC photonic die 119 and the IC electronic die 121 are provided in the same recess, although it will be understood that the IC photonic die 119 and the IC electronic die 121 may be located in different recesses. The package structure 170 of FIG. 24 differs from the package structure 170 of FIG. 15 in that the IC photonic die 119 and the IC electronic die 121 are arranged side-by-side rather than being vertically stacked and bonded together as described above with reference to the embodiment shown in FIG. 15. The IC photonic die 119 and the IC electronic die 121 may be located immediately adjacent to one another, or may be laterally spaced from one another. In embodiments in which the IC photonic die 119 and the IC electronic die 121 are laterally spaced from one another, the gap fill dielectric material 131 may be located within a gap between the IC photonic die 119 and the IC electronic die 121. In various embodiments, electrical signals may be transmitted between the IC photonic die 119 and the IC electronic die 121 via metal interconnect features 135 of the redistribution structure 133.

The embodiment of FIG. 24 also differs from the embodiment of FIG. 15 in that the interposer 160 includes an integrated optical waveguide 113 that includes a first optical waveguide segment 113a that directs optical signals along a first direction (i.e., a horizontal direction) and a second optical waveguide segment 113b that directs optical signals along a second direction (i.e., a vertical direction). The optical waveguide 113 further includes an optical component 185 that redirects optical signals between the first optical waveguide segment 113a and the second optical waveguide segment 113b. The second optical waveguide segment 113b in this embodiment is located below the IC photonic die 119. Thus, optical signals may be transmitted between the optical waveguide 113 and the IC photonic die 119 on a bottom surface of the IC photonic die 119. In other embodiments, the optical waveguide 113 may be optically coupled to the IC photonic die 119 on a side surface or an upper surface of the IC photonic die 119.

In the embodiment of FIG. 24, the first optical waveguide segment 113a of the optical waveguide 113 includes a core material 109 embedded in the substrate 100 of the interposer 160 such that the substrate 100 may function as a first cladding material on the bottom surfaces and sidewalls of the core material 109. The second cladding material 111 is located over the upper surface of the core material 109. The second optical waveguide segment 113b includes a second core material 109 extending in a vertical direction and laterally surrounded by the second cladding material 111. In other embodiments, a first cladding material 107 may be located along the bottom surface of the core material 109 of the first optical waveguide segment 113, such as shown in the embodiments of FIGS. 14-17, 22 and 23.

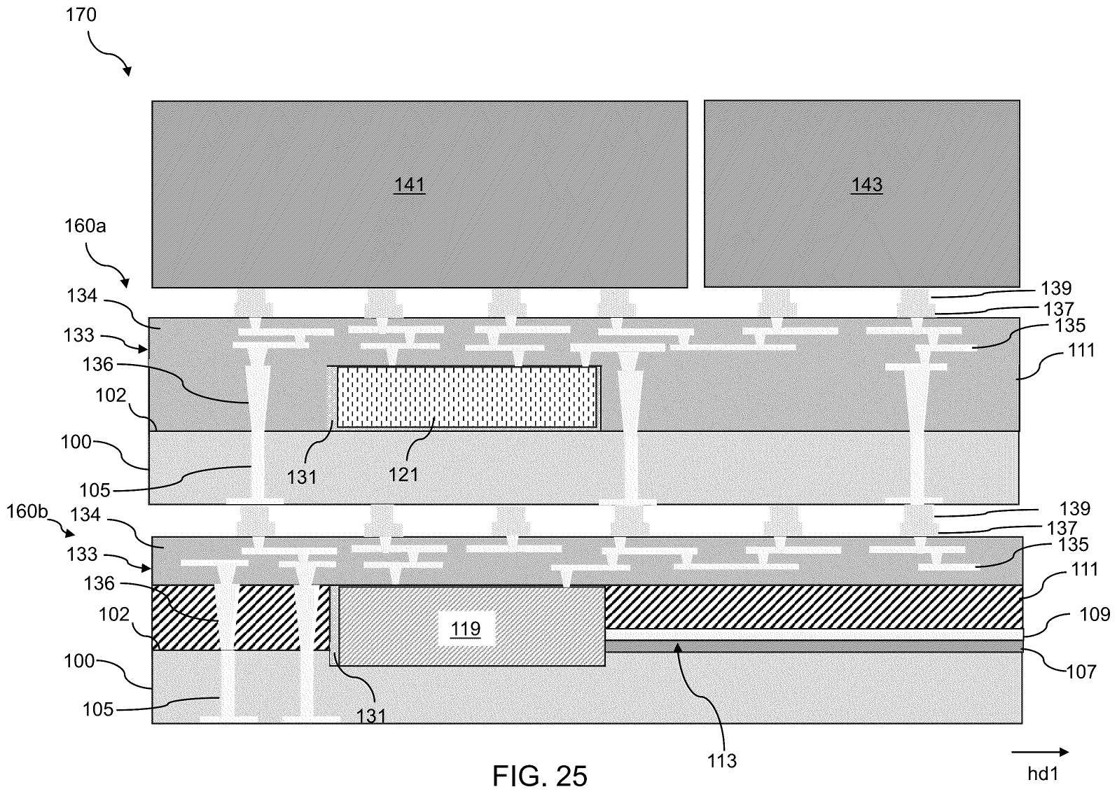

FIG. 25 is a vertical cross-sectional view of a package structure 170 including a first interposer 160a and a second interposer 160b according to another embodiment of the present disclosure. Referring to FIG. 25, the package structure 170 includes a first interposer 160a including an integrated IC electronic die 121 and a second interposer 160b including an integrated IC photonic die 119 and an optical waveguide 113. A first semiconductor die 141 and a second semiconductor die 143 are mounted over an upper surface of the first interposer 160a, and the first interposer 160a is mounted over the upper surface of the second interposer 160b.

Referring again to FIG. 25, the first interposer 160a and the second interposer 160b may both be similar to the interposer 160 described above with reference to FIG. 16. That is, each of the first interposer 160a and the second interposer 160b may include a substrate 100, a plurality of through-substrate vias 105 extending through the substrate 100, and a redistribution structure 133 over the first side 102 of the substrate 100. The IC electronic die 121 may be provided in a recess 118 in the first interposer 160a (see FIGS. 11-13). The recess 118 may be formed within the substrate 100 and/or within a dielectric material 134 formed over the substrate 100 of the first interposer 160a. The IP photonic die 119 may similarly be provided in a recess 118 in the second interposer 160b. The second interposer 160b may also include an optical waveguide 113 including a core material 109 surrounded by cladding material 107, 111, where the optical waveguide 113 may be optically coupled to the IP photonic die 119.

In various embodiments, the first and second semiconductor dies 141, 143, the first interposer 160a, and the second interposer 160b may be vertically-stacked. The first semiconductor die 141 and the second semiconductor die 143 may be mounted to the upper surface of the first interposer 160a by corresponding pairs of first bonding structures 137 and second bonding structures 139. The first interposer 160a may be mounted to the upper surface of the second interposer 160b by corresponding pairs of first bonding structures 137 and second bonding structures 139. Electrical signals between the IC photonic die 119 of the second interposer 160b and the IC electronic die 121 of the first interposer 160a may be transmitted via metal interconnect features 135 in the redistribution structure 133 of the second interposer 160b, the first and second bonding structures 137, 139 that couple the second interposer 160b the first interposer 160a, through-substrate vias 105 through the substrate 100 of the first interposer 160a, and metal interconnect features 135 in the redistribution structure 133 of the first interposer 160a. Electrical signals between the IC electronic die 121 of the first interposer 160a and the first semiconductor die 141 and the second semiconductor die 143 may be transmitted via metal interconnect features 135 of the redistribution structure 133 of the first interposer 160a and the first bonding structures 137 and the second bonding structures 139 that bond the first semiconductor die 141 and the second semiconductor die 143 to the first interposer 160a. In some embodiments, the second interposer 160b may be subsequently mounted to a package substrate 150 to form a semiconductor package 175 as described above with reference to FIG. 16.

Although the package structure 170 of FIG. 25 shows the first interposer 160a bonded to the second interposer 160b via metal bump (e.g., microbump) bonding structures 137, 139, it will be understood that other bonding techniques, such as an above-described direct bonding technique, may be used to bond the first interposer 160a and the second interposer 160b.

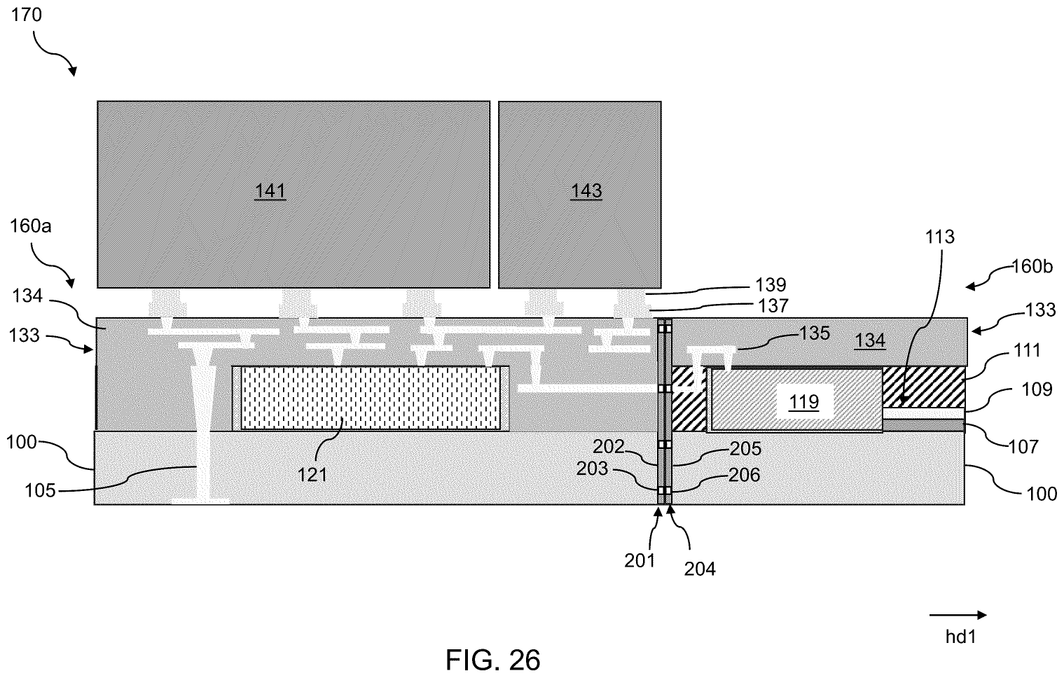

FIG. 26 is a vertical cross-sectional view of a package structure 170 including a first interposer 160a and a second interposer 160b according to another embodiment of the present disclosure. The package structure 170 shown in FIG. 26 may be similar to the package structure 170 described above with reference to FIG. 25. Thus, repeated discussion of like features is omitted for brevity. The package structure 170 shown in FIG. 26 differs from the package structure 170 of FIG. 25 in that the first interposer 160a and the second interposer 160b are arranged side-by-side rather than in a vertically stacked configuration. In various embodiments, the first interposer 160a and the second interposer 160b may be bonded via bonding structures located on the side surfaces of the first interposer 160a and the second interposer 160b. In the embodiment of FIG. 26, the first interposer 160a is bonded to the second interposer 160b via a metal-to-metal (M-M) and dielectric-to-dielectric (D-D) direct bonding technique. A first bonding layer 201 including a first dielectric material 202 having first bonding pads 203 embedded therein may be formed over a side surface of the first interposer 160a. A second bonding layer 204 including a second dielectric material 205 having second bonding pads 206 embedded therein may be formed over a side surface of the second interposer 160b. A direct bonding process such as described above with reference to FIG. 13 may be performed to bond the first bonding layer 201 and the second bonding layer 204 and thereby bond the first interposer 160a to the second interposer 160b. It will be understood that other bonding techniques for bonding the first interposer 160a to the second interposer 160b, such as a metal bump (e.g., microbump) bonding technique may also be utilized.

Electrical signals between the IC photonic die 119 of the second interposer 160b and the IC electronic die 121 of the first interposer 160a may be transmitted via metal interconnect features 135 in the redistribution structure 133 of the second interposer 160b, the first and second bonding pads 203 and 206 of the first and second bonding layers 201 and 204, and metal interconnect features 135 in the redistribution structure 133 of the first interposer 160a. Electrical signals between the IC electronic die 121 of the first interposer 160a and the first semiconductor die 141 and the second semiconductor die 143 may be transmitted via metal interconnect features 135 of the redistribution structure 133 of the first interposer 160a and the first bonding structures 137 and the second bonding structures 139 that bond the first semiconductor die 141 and the second semiconductor die 143 to the first interposer 160a. In some embodiments, the first interposer 160a and the second interposer 160b may be subsequently mounted to a package substrate 150 to form a semiconductor package 175 as described above with reference to FIG. 16.

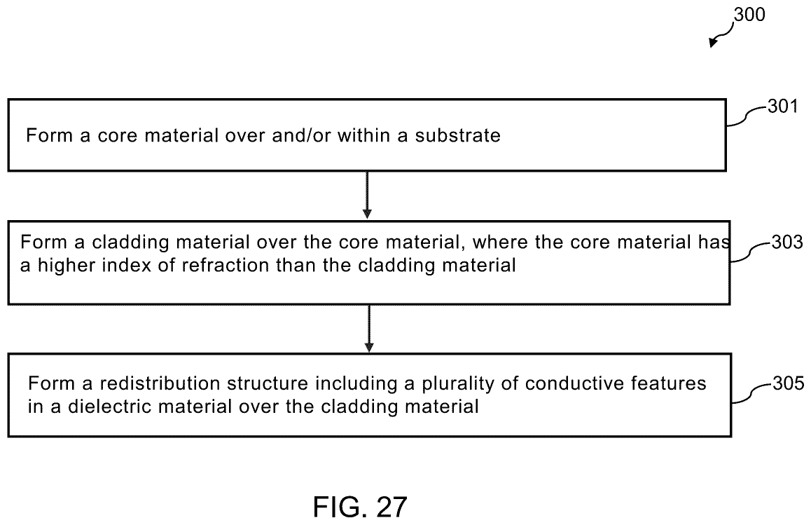

FIG. 27 is a flowchart illustrating a method 300 of fabricating an interposer 160 for a semiconductor package 175 according to various embodiments of the present disclosure. Referring to FIGS. 2, 8A-8C and 27, in step 301 of method 300, a core material 109 may be formed over and/or within a substrate 100. Referring to FIGS. 2, 9A-9C and 27, in step 303 of method 300, a cladding material 111 may be formed over the core material 109, where the core material 109 has a higher index of refraction than the cladding material 111. Referring to FIGS. 14, 22 and 27, in step 305 of method 300, a redistribution structure 133 including a plurality of conductive features 135 in a dielectric material 134 may be formed over the cladding material 111.

Referring to all drawings and according to various embodiments of the present disclosure, a semiconductor package structure includes a substrate 100 having a first side 102 and a second side 104 and electrically conductive features 105 extending between the first side 102 and the second side 104 of the substrate 100, a redistribution structure 133 over the first side 102 of the substrate 100, where the redistribution structure 133 includes a plurality of metal interconnect features 135 in a dielectric material 134, a semiconductor die 141, 143 mounted over an upper surface of the redistribution structure 133, where the metal interconnect features 135 of the redistribution structure electrically couple the semiconductor die 141, 143 to at least one electrically conductive feature 105 extending between the first side 102 and the second side 104 of the substrate 100, and an optical waveguide 113 located between the first side 102 of the substrate 100 and the upper surface of the redistribution structure 133.

In an embodiment, the optical waveguide 113 includes a core material 109 surrounded by a cladding material 107, 111, where the core material 109 has an index of refraction that is greater than an index of refraction of the cladding material 107, 111.

In another embodiment, at least a portion of the cladding material 107, 111 is located between the redistribution structure 133 and the substrate 100.

In another embodiment, the cladding material includes a first cladding material 107 on a bottom surface of the core material 109 and a second cladding material 111 over side surfaces and an upper surface of the core material 109.

In another embodiment, the cladding material includes a portion of the substrate 100 surrounding the core material 109 on a bottom surface and side surfaces of the core material 109, and a second cladding material 111 over an upper surface of the core material 109.

In another embodiment, the interposer 160 further includes an integrated circuit (IC) photonic die 119 optically coupled to the optical waveguide 113, where the IC photonic die 119 is located between the substrate 100 and the redistribution structure 133.

In another embodiment, the interposer 160 further includes an integrated circuit (IC) electronic die 121 electrically coupled to the IC photonic die 119.

In another embodiment, the IC photonic die 119 and the IC electronic die 121 are vertically stacked and bonded together by bonding structures 123, 127, where the IC electronic die 121 is electrically coupled to the IC photonic die 119 by the bonding structures 123, 127.

In another embodiment, the IC electronic die 121 is electrically coupled to the IC photonic die 119 by the conductive features 135 of the redistribution structure 133.

In another embodiment, the optical waveguide 113 includes comprises a first optical waveguide segment 113a extending in a horizontal direction, a second optical waveguide segment 113b extending in a vertical direction, and an optical element 185 located between the first optical waveguide segment 113a and the second optical waveguide segment 113b configured to change a direction of photon travel within the optical waveguide 113, where the optical element comprises a triangular-shaped mirror 185a, a grating 185b, or a bubble-shaped element 185c.

Another embodiment is drawn to a package structure 170 including an interposer structure 160 including a substrate 100, a redistribution structure 133 over the substrate 100, where the redistribution structure 133 includes a plurality of conductive features 135 in a dielectric material 134, and an optical waveguide 113 located over and/or within the substrate 100, a semiconductor die 141, 143 mounted over an upper surface of the interposer structure 160 via one or more bonding structures 137, 139, where the semiconductor die 141, 143 is electrically coupled to the conductive features 135 of the redistribution structure 133 via the one or more bonding structures 137, 139, an integrated circuit (IC) photonic die 119 optically coupled to the optical waveguide 113, and an IC electronic die 121 electrically coupled to the IC photonic die 119 and to the semiconductor die 141, 143.

In an embodiment, the IC photonic die 119 is located on the interposer structure 160.

In another embodiment, the IC electronic die 121 is located on the interposer structure 160, where the IC electronic die 121 is electrically coupled to the semiconductor die 141, 143 via the conductive features 135 of the redistribution structure 133 and the one or more bonding structures 137, 139.

In another embodiment, the IC photonic die 119 and the IC electronic die 121 are located on the semiconductor die 141, 143, the optical waveguide 113 includes an optical via 113b extending in a vertical direction to the upper surface of the interposer structure 160, and the semiconductor die 141, 143 is mounted to the interposer structure 160 such that the IC photonic die 119 is located above the optical via 113b of the optical waveguide 113.

In another embodiment, the interposer structure 160 includes a first interposer 160a including a first substrate 100, a first redistribution structure 133 over the first substrate 100, where the first redistribution structure 133 includes a first plurality of conductive features 135 in a first dielectric material 134, and the optical waveguide 113 located over and/or within the first substrate 100, and a second interposer 160b including a second substrate 100, a second redistribution structure 133 over the second substrate 100, where the second redistribution structure 133 includes a second plurality of conductive features 135 in a second dielectric material 134, and the IC electronic die 121, where the first interposer 160a is bonded to the second interposer 160b by interposer bonding structures (137, 139), the semiconductor die 141, 143 is mounted over an upper surface of the second interposer 160b by the one or more bonding structures 137, 139, the IC electronic die 121 is electrically coupled to the semiconductor die 141, 143 by the second plurality of conductive features 135 of the second redistribution structure 133 and the one or more bonding structures 137, 139, and the IC photonic die 119 is electrically coupled to the IC electronic die 121 by the first plurality of conductive features 135 of the first redistribution structure 133, the interposer bonding structures (137, 139, 201, 204), and the second plurality of conductive features 135 of the second redistribution structure 133.

Another embodiment is drawn to a method of fabricating an interposer 160 for a semiconductor package 175 that includes forming a core material 109 over and/or within a substrate 100, forming a cladding material 111 over the core material 109, where the core material 109 has a higher index of refraction than the cladding material 111, and forming a redistribution structure 133 including a plurality of conductive features 135 in a dielectric material 134 over the cladding material 111.

In another embodiment, forming the core material 109 includes performing an etching process through a patterned mask 114 to remove portions of the substrate 100 to provide a recess 115 in the substrate 100, depositing the core material 109 within the recess 115, where the core material 109 has a higher index of refraction than the substrate 100, and where forming the cladding material 111 over the core material 109 includes depositing the cladding material 111 over the substrate 100 and the core material 109 within the recess 115.

In another embodiment, the method further includes forming a recess 118 in the cladding material 111, where the core material 109 is exposed along a sidewall 120 of the recess 118, and providing an integrated circuit (IC) photonic die 119 within the recess 118 that is optically coupled to the core material 109, where the redistribution structure 133 is formed over the IC photonic die 119.

In another embodiment, the method further includes bonding an IC electronic die 121 to the IC photonic die 119 located within the recess 118, where the redistribution structure 133 is formed over the IC electronic die 121.

The foregoing outlines features of several embodiments so that those skilled in the art may better understand the aspects of the present disclosure. Those skilled in the art should appreciate that they may readily use the present disclosure as a basis for designing or modifying other processes and structures for achieving the same purposes and/or the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a substrate having a first side and a second side and electrically conductive features extending between the first side and the second side of the substrate;
a redistribution structure over the first side of the substrate, wherein the redistribution structure comprises a plurality of metal interconnect features in a dielectric material;
a semiconductor die mounted over an upper surface of the redistribution structure, wherein the metal interconnect features of the redistribution structure electrically couple the semiconductor die to at least one electrically conductive feature extending between the first side and the second side of the substrate; and
an optical waveguide located between the first side of the substrate and the upper surface of the redistribution structure.

2. The interposer of claim 1, wherein the optical waveguide comprises a core material surrounded by a cladding material, wherein the core material has an index of refraction that is greater than an index of refraction of the cladding material.

3. The interposer of claim 2, wherein at least a portion of the cladding material is located between the redistribution structure and the substrate.

4. The interposer of claim 3, wherein the cladding material comprises a first cladding material on a bottom surface of the core material and a second cladding material over side surfaces and an upper surface of the core material.

5. The interposer of claim 3, wherein the cladding material comprises a portion of the substrate surrounding the core material on a bottom surface and side surfaces of the core material, and a second cladding material over an upper surface of the core material.

6. The interposer of claim 1, further comprising an integrated circuit (IC) photonic die optically coupled to the optical waveguide, wherein the IC photonic die is located between the substrate and the redistribution structure.

7. The interposer of claim 6, further comprising an integrated circuit (IC) electronic die electrically coupled to the IC photonic die.

8. The interposer of claim 7, wherein the IC photonic die and the IC electronic die are vertically stacked and bonded together by bonding structures, wherein the IC electronic die is electrically coupled to the IC photonic die by the bonding structures.

9. The interposer of claim 7, wherein the IC electronic die is electrically coupled to the IC photonic die by the plurality of conductive features of the redistribution structure.

10. The interposer of claim 1, wherein the optical waveguide comprises:
a first optical waveguide segment extending in a horizontal direction;
a second optical waveguide segment extending in a vertical direction; and
an optical element located between the first optical waveguide segment and the second optical waveguide segment configured to change a direction of photon travel within the optical waveguide, wherein the optical element comprises a triangular-shaped mirror, a grating, or a bubble-shaped element.

11. A package structure, comprising:
an interposer structure, comprising:
a substrate;
a redistribution structure over the substrate, wherein the redistribution structure comprises a plurality of conductive features in a dielectric material; and
an optical waveguide located over the substrate;
a semiconductor die mounted over an upper surface of the interposer structure via one or more bonding structures, wherein the semiconductor die is electrically coupled to the plurality of conductive features of the redistribution structure via the one or more bonding structures;
an integrated circuit (IC) photonic die optically coupled to the optical waveguide; and
an IC electronic die electrically coupled to the IC photonic die and to the semiconductor die.

12. The package structure of claim 11, wherein the IC photonic die is located on the interposer structure.

13. The package structure of claim 12, wherein the IC electronic die is located on the interposer structure, wherein the IC electronic die is electrically coupled to the semiconductor die via the plurality of conductive features of the redistribution structure and the one or more bonding structures.

14. The package structure of claim 11, wherein the IC photonic die and the IC electronic die are located on the semiconductor die, the optical waveguide comprises an optical via extending in a vertical direction to the upper surface of the interposer structure, and the semiconductor die is mounted to the interposer structure such that the IC photonic die is located above the optical via of the optical waveguide.

15. The package structure of claim 11, wherein the interposer structure comprises:
a first interposer, comprising:
a first substrate;
a first redistribution structure over the first substrate, wherein the first redistribution structure comprises a first plurality of conductive features in a first dielectric material; and
the optical waveguide located over the first substrate; and
a second interposer, comprising:
a second substrate;
a second redistribution structure over the second substrate, wherein the second redistribution structure comprises a second plurality of conductive features in a second dielectric material; and
the IC electronic die, wherein:
the first interposer is bonded to the second interposer by interposer bonding structures;
the semiconductor die is mounted over an upper surface of the second interposer by the one or more bonding structures;
the IC electronic die is electrically coupled to the semiconductor die by the second plurality of conductive features of the second redistribution structure and the one or more bonding structures; and
the IC photonic die is electrically coupled to the IC electronic die by the first plurality of conductive features of the first redistribution structure, the interposer bonding structures, and the second plurality of conductive features of the second redistribution structure.

16. A method of fabricating an interposer for a semiconductor package, comprising:
forming a core material on a substrate;
forming a cladding material over the core material, wherein the core material has a higher index of refraction than the cladding material; and
forming a redistribution structure comprising a plurality of conductive features in a dielectric material over the cladding material.

17. The method of claim 16, further comprising:
depositing a first cladding material over a first side of the substrate, wherein forming the core material comprises:
depositing the core material over the first cladding material; and
performing an etching process through a patterned mask to remove portions of the core material and the first cladding material to provide a strip-shaped layer stack including the core material overlying the first cladding material, and wherein forming the cladding material over the core material comprises:
depositing a second cladding material over an upper surface and side surfaces of the layer stack.

18. The method of claim 16, wherein forming the core material comprises:
performing an etching process through a patterned mask to remove portions of the substrate to provide a recess in the substrate; and
depositing the core material within the recess, wherein the core material has a higher index of refraction than the substrate, and wherein forming the cladding material over the core material comprises depositing the cladding material over the substrate and the core material within the recess.

19. The method of claim 16, further comprising:
forming a recess in the cladding material, wherein the core material is exposed along a sidewall of the recess; and
providing an integrated circuit (IC) photonic die within the recess that is optically coupled to the core material, wherein the redistribution structure is formed over the IC photonic die.

20. The method of claim 19, further comprising:
bonding an IC electronic die to the IC photonic die located within the recess, wherein the redistribution structure is formed over the IC electronic die.
